(19) United States
(12) Patent Application Publication
(10) Pub. No.: US 2024/0128715 A1
(43) Pub. Date: Apr. 18, 2024

(54) PHOTODIODE CHIP, PHOTODIODE, AND METHOD AND FOR CONTROLLING WAVELENGTH OF PHOTODIODE

(71) Applicant: PHOGRAIN TECHNOLOGY (SHENZHEN) CO., LTD., Shenzhen, Guangdong (CN)

(72) Inventors: Hongliang LIU, Shenzhen, Guangdong (CN); Yanwei YANG, Shenzhen, Guangdong (CN); Yan ZOU, Shenzhen, Guangdong (CN); Ying LI, Shenzhen, Guangdong (CN); Xupeng ZHANG, Shenzhen, Guangdong (CN)

(73) Assignee: PHOGRAIN TECHNOLOGY (SHENZHEN) CO., LTD., Shenzhen, Guangdong (CN)

(21) Appl. No.: 18/274,582

(22) PCT Filed: Jun. 11, 2021
(86) PCT No.: PCT/CN2021/099714

§ 371 Date: Jul. 27, 2023

(30) Foreign Application Priority Data
Jun. 12, 2020 (CN) 202010537364.9
Jun. 12, 2020 (CN) 202010537365.3
Jun. 12, 2020 (CN) 202010538227.7
Jun. 12, 2020 (CN) 202021092723.6
Jun. 12, 2020 (CN) 202021096025.3

(51) Int. Cl. H01S 5/062; H01S 5/06; H01S 5/12; H01S 5/22

(52) U.S. Cl. CPC H01S 5/062; H01S 5/0612; H01S 5/12; H01S 5/22

(57) ABSTRACT

A photodiode chip, a photodiode, and a method for controlling a wavelength of a photodiode are provided. The photodiode chip sequentially incudes, above a substrate, a grating layer and a ridge waveguide layer. The ridge waveguide layer includes multiple ridge waveguides. Each of the multiple ridge waveguides corresponds to one column of gratings in the multiple columns of gratings below. The grating layer includes multiple columns of gratings. At least two columns of gratings have different grating period pitches.

### CROSS-REFERENCE TO RELATED APPLICATION(S)

This application is a National Stage of International Application No. PCT/CN2021/099714, field Jun. 11, 2021, which claims priority to Chinese Patent Application No. 202010538227.7, filed Jun. 12, 2020, claims priority to Chinese Patent Application No. 202010537365.3, filed Jun. 12, 2020, claims priority to Chinese Patent Application No. 202010537364.9, filed Jun. 12, 2020, claims priority to Chinese Patent Application No. 202021096025.3, filed Jun. 12, 2020, and claims priority to Chinese Patent Application No. 202021092723.6, filed Jun. 12, 2020, the disclosures of which are hereby incorporated by reference in their entireties.

### TECHNICAL FIELD

The present disclosure generally relates to the field of semiconductor technologies, and more specifically, to a photodiode chip, a photodiode, and a method for controlling a wavelength of a photodiode.

### BACKGROUND

A photodiode chip includes a photodetector chip that receives light and a chip that emits light. A laser transmitter includes a chip that emits light and is a device for emitting laser light. An existing laser transmitter is usually a single-laser transmitter, that is, a transmitter that emits one beam of laser light or one piece of laser light having the same wavelength, in other words, emits laser light having a single wavelength. In the field of optical transmission, optical transmission usually uses wavelength division multiplexing. Wavelength division multiplexing (WDM) is a technology that joins two or more optical carrier signals having different wavelengths (carrying various information) at a transmit end by using a multiplexer, and couples the signals to the same optical fiber of an optical line for transmission. To implement WDM, multiple single-wavelength laser transmitters are required at the transmit end. Single-wavelength laser transmitters need to be individually packaged and coupled. For example, if light having 40 different wavelengths is to be emitted, the usual practice is to use 40 individually packaged single-wavelength laser transmitters, and each individually packaged single-wavelength laser transmitter is packaged by a laser chip. Therefore, 40 different wavelengths mean that 40 different laser chips and transistor outline (TO) devices are required to be packaged and coupled separately. This may cause the entire system to be large in size, expensive, and time-consuming and labor-intensive to install.

A laser transmitter is a device that can emit laser light. An existing laser transmitter is usually a single-laser transmitter, that is, a transmitter that emits one beam or piece of laser light, and emits laser light having a single wavelength. In the field of optical communication transmission, a dense optical wavelength multiplexing transmission system is usually used to increase an optical fiber transmission bandwidth as much as possible. WDM is a technology that joins two or more optical carrier signals having different wavelengths at a transmit end by using a multiplexer, and couples the signals to the same optical fiber of an optical line for transmission. That is, this technology simultaneously transmits two or more optical signals having different wavelengths in the same optical fiber. To implement WDM, multiple single-wavelength laser transmitters are required at the transmit end. Single-wavelength laser transmitters need to be individually packaged and coupled. However, this may cause the entire system to be large in size, complex to assemble, and costly.

In the field of optical transmission, optical transmission usually uses WDM. WDM is a technology that joins two or more optical carrier signals having different wavelengths (carrying various information) at a transmit end by using a multiplexer, and couples the signals to the same optical fiber of an optical line for transmission. That is, the technology simultaneously transmits two or more optical signals having different wavelengths in the same optical fiber. To implement WDM, multiple single-wavelength laser transmitters are required at the transmit end. Single-wavelength laser transmitters need to be individually packaged and coupled. This may cause the entire system to be large in size, costly, and time-consuming and labor-intensive to install.

### SUMMARY

In a first aspect, a photodiode chip is provided in the present disclosure. The photodiode includes a substrate. The chip includes a grating layer above the substrate and a ridge waveguide layer located above the grating layer. The ridge waveguide layer includes multiple ridge waveguides. The grating layer includes multiple columns of gratings. Each of the multiple ridge waveguides corresponds to one column of gratings in the multiple columns of gratings below, and at least two columns of gratings in the multiple columns of gratings have different grating period pitches.

In a second aspect, a photodiode is provided in the present disclosure. The photodiode includes a photodiode chip, a semiconductor temperature controller, and a driver electronic chip. The photodiode chip includes a substrate. The chip includes a grating layer above the substrate and a ridge waveguide layer located above the grating layer. The ridge waveguide layer includes multiple ridge waveguides. The grating layer includes multiple columns of gratings. Each of the multiple ridge waveguides corresponds to one column of gratings in the multiple columns of gratings below, and at least two columns of gratings in the multiple columns of gratings have different grating period pitches. The semiconductor temperature controller is located on one side of the photodiode chip and configured to regulate a temperature of the photodiode chip to a target temperature. The driver electronic chip is configured to perform energization control on the photodiode chip that is at the target temperature, to make the photodiode chip at the target temperature emit target laser light having a wavelength including a corresponding target wavelength. The target wavelength is related to the target temperature. The target laser light has a spectrum width.

In a third aspect, a method for controlling a wavelength of a photodiode is provided in the present disclosure. The method is applied to a laser apparatus. The laser apparatus includes a photodiode, a semiconductor temperature controller, and a driver electronic chip. The photodiode includes a photodiode chip. The photodiode includes a substrate. The chip includes a grating layer above the substrate and a ridge waveguide layer located above the grating layer. The ridge waveguide layer includes multiple ridge waveguides. The grating layer includes multiple columns of gratings. Each of the multiple ridge waveguides corresponds to one column of gratings in the multiple columns of gratings below, and at least two columns of gratings in the multiple columns of gratings have different grating period pitches. The semiconductor temperature controller is located on one side of the photodiode chip and configured to regulate a temperature of the photodiode chip to a target temperature. The driver electronic chip is configured to perform energization control on the photodiode chip that is at the target temperature, to make the photodiode chip at the target temperature emit target laser light having a wavelength including a corresponding target wavelength. The target wavelength is related to the target temperature. The target laser light has a spectrum width. The photodiode chip is a photodiode chip. The photodiode chip is provided with multiple light-emitting strips and multiple pairs of electrodes. Each light-emitting strip corresponds to one pair of electrodes. The method includes the following. A user instruction is received. The semiconductor temperature controller is controlled, according to the user instruction, to control a temperature of the photodiode chip, to make the temperature of the photodiode chip reach a current target temperature at a current moment. A corresponding target light-emitting strip on the photodiode chip is determined based on the current target temperature. The driver electronic chip is controlled to energize one pair of electrodes corresponding to the target light-emitting strip, to make the pair of electrodes corresponding to the target light-emitting strip act on the target light-emitting strip, to enable the target light emitting strip to emit target laser light having a wavelength including a target wavelength. The target laser light has a spectrum width. The semiconductor temperature controller is controlled, according to the user instruction, to control the temperature of the photodiode chip, to make the temperature of the photodiode chip reach a next-moment target temperature at a next moment of the current moment. By using the next-moment target temperature as the current target temperature, determining the corresponding target light-emitting strip on the photodiode chip based on the current target temperature is performed, until all target laser light having different target wavelengths are emitted. The target laser light has a spectrum width.

### BRIEF DESCRIPTION OF THE DRAWINGS

The accompanying drawings herein are incorporated into and constitute a part of the description, illustrate embodiments consistent with the present disclosure, and are used together with the description to explain the principles of the present disclosure.

To describe technical solutions in the embodiments of the present disclosure or in the prior art more clearly, the accompanying drawings to be used for description of the embodiments or the prior art will be briefly described below. Apparently, those of ordinary skill in the art may derive other drawings from these accompanying drawings without any creative effort.

FIG. 1 is a schematic diagram of a structure of a photodiode chip according to an embodiment;

FIG. 2 is a schematic top view of a grating layer according to an embodiment;

FIG. 3 is a diagram of a change curve of a lasing wavelength and a temperature according to an embodiment;

FIG. 4 is a schematic cross-sectional view of a photodiode chip according to an embodiment;

FIG. 5 is a front view of a photodiode chip according to an embodiment;

FIG. 6 is a schematic cutaway view of a photodiode chip according to an embodiment;

FIG. 7 is a schematic flowchart of a method for manufacturing a photodiode chip according to an embodiment;

FIG. 8 is an epitaxial cutaway view after a grating is manufactured according to an embodiment;

FIG. 9 is an epitaxial cutaway view after a corrosion stop layer and a positively doped top-layer are grown according to an embodiment;

FIG. 10 is an epitaxial cutaway view after a ridge waveguide layer and an etching-stop dielectric film are obtained through etching according to an embodiment;

FIG. 11 is an epitaxial cutaway view after an electrode is manufactured;

FIG. 12 is an epitaxial cutaway view after an insulating dielectric film is grown;

FIG. 13 is an epitaxial cutaway view after a first opening is defined for one ridge waveguide according to an embodiment;

FIG. 14 is an epitaxial cutaway view after a negative electrode contact layer is evaporated according to an embodiment;

FIG. 15 is a front view of a chip after a reflective film and an antireflective film are evaporated according to an embodiment;

FIG. 16 is a structural block diagram of a dense wavelength division multiplexing (DWDM) transmission system according to an embodiment;

FIG. 17 is a schematic flowchart of a method for controlling a wavelength of a photodiode according to an embodiment;

FIG. 18 is a schematic diagram of a structure of a photodiode according to an embodiment;

FIG. 19 is a diagram of a curve of a temperature of a photodiode chip and a lasing wavelength according to an embodiment;

FIG. 20 is a schematic cross-sectional view of a photodiode chip according to an embodiment;

FIG. 21 is a front view of a photodiode chip according to an embodiment;

FIG. 22 is a schematic top view of a grating layer according to an embodiment;

FIG. 23 is a schematic cutaway view of a photodiode chip according to an embodiment;

FIG. 24 is a schematic flowchart of a method for controlling a wavelength of a photodiode according to an embodiment;

FIG. 25 is a structural block diagram of an apparatus for controlling a wavelength of a photodiode according to an embodiment; and

FIG. 26 is a front top view of a photodiode chip according to an embodiment.

Reference numerals in the accompanying drawings are as follows:
light-emitting strip 1, positive electrode 2, photodiode chip 10, semiconductor temperature controller 20, driver electronic chip 30, ceramic carrier 40, ridge waveguide 100 (ridge waveguide 101; ridge waveguide 102), grating 200 (grating 201; grating 202; grating 203), electrode 400 (electrode 401; electrode 402), insulating dielectric film 300 (first insulating dielectric film 301; second insulating dielectric film 302), electrode connection line 500 (electrode connection line 501), pad 700, opening 600 (first opening 601; second opening 602), substrate 000a, ridge waveguide layer 100a, grating layer 200a, insulating dielectric film layer 300a, electrode layer 400a, electrode connection line layer 500a, buffer layer 800a, lower waveguide layer 900a, quantum well layer 1000a, upper waveguide layer 1100a, corrosion stop layer 1200a, positively doped top-layer 100b, etching-stop dielectric film 400b, negative electrode contact layer 1300a, antireflective film 1400a, reflective film 1500a.

### DETAILED DESCRIPTION

In order to make the objectives, technical solutions and advantages of embodiments of the present disclosure clearer, the technical solutions in the embodiments of the present disclosure will be clearly and completely described below with reference to the accompanying drawings in the embodiments of the present disclosure. Apparently, the described embodiments are a part, but not all of the embodiments of the present disclosure. Based on the embodiments of the present disclosure, all other embodiments obtained by those of ordinary skill in the art without creative efforts fall within the scope of protection of the present disclosure.

In order to understand the technical features, objectives, and effects of the present disclosure more clearly, the specific embodiments of the present disclosure are described herein in detail with reference to the accompanying drawings. In the following description, it should be understood that orientation or position relationships indicated by “front”, “rear”, “up”, “down”, “left”, “right”, “longitudinal”, “transverse”, “vertical”, “horizontal”, “top”, “bottom”, “inside”, “outside”, “head”, “tail”, and the like are based on orientation or position relationships shown in the accompanying drawings, are constructed and operated in specific orientations, and are merely for ease of description of the present technical solutions, rather than indicating or implying that the apparatuses or elements referred to must have a specific orientation, and therefore cannot be construed as limiting the present disclosure.

It should be further noted that, unless expressly stated or limited otherwise, the terms such as “mounting”, “connection”, “connected”, “fixing”, and “providing” should be interpreted broadly, for example, either a fixed or detachable connection, or integration; may be a mechanical connection or an electrical connection; and or may be a direct connection or an indirect connection by means of an intermediate medium, or may be communication between interiors of two elements or interaction between the two elements. When an element is referred to as being “above” or “below” another element, the element can be “directly” or “indirectly” above the another element, or one or more intervening elements may be present. The terms “first”, “second”, “third”, and the like are merely for ease of description of the present technical solutions, and cannot be interpreted as indicating or implying the relative importance or implicitly specifying the number of indicated technical features. Therefore, the features defined with “first”, “second”, “third”, and the like may explicitly or implicitly include one or more of the features. For those of ordinary skill in the art, specific meanings of the foregoing terms in the present disclosure may be understood based on specific situations.

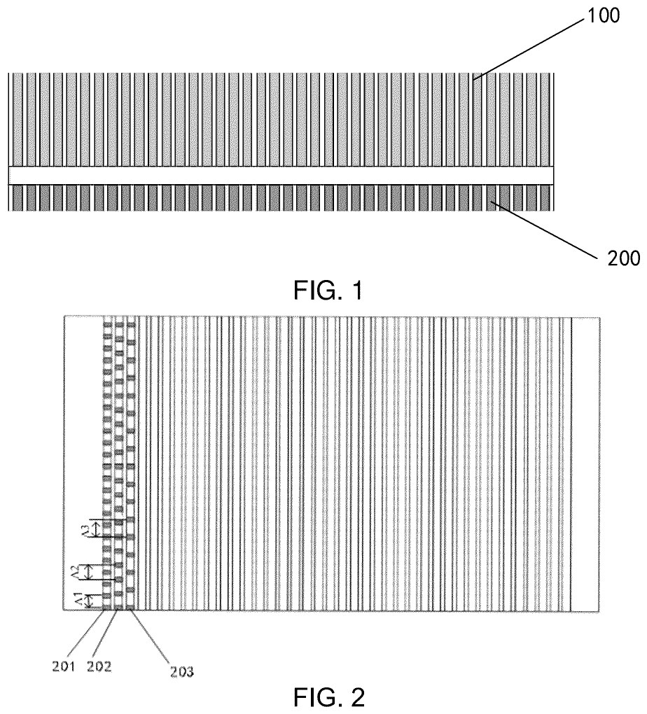

Referring to FIG. 1 to FIG. 6, the photodiode chip includes a substrate 000a, the chip includes a grating layer 200a above the substrate 000a and a ridge waveguide layer 100a above the grating layer 200a, the ridge waveguide layer 100a includes multiple ridge waveguides 100 (for example, a ridge waveguide 101 and a ridge waveguide 102), the grating layer 200a includes multiple columns of gratings 200 (for example, gratings 201, gratings 202, and gratings 203), and each of the ridge waveguides 100 corresponds to one column of gratings 200 in the multiple columns of gratings 200 below, for example: the ridge waveguide 101 corresponds to the gratings 201 below, and the ridge waveguide 102 corresponds to the gratings 202 below. At least two columns of gratings 200 in the multiple columns of gratings 200 have different grating period pitches. For example, the gratings 201 and the gratings 202 have different period pitches. A grating period pitch determines a spectrum width of laser light obtained after wavelength screening by using the column of gratings 200, and different wavelengths can be screened by using different grating period pitches.

In some embodiments, any two columns of gratings 200 in the multiple columns of gratings 200 have different grating period pitches. In another specific embodiment, any grating 200 in the multiple columns of gratings 200 has a different period pitch from an adjacent grating 200.

FIG. 2 is a schematic top view of a grating layer according to an embodiment. Referring to FIG. 2, the grating layer includes multiple columns of gratings 200 (for example, gratings 201, gratings 202, and gratings 203), and a grating period pitch A of one column of gratings of the gratings 201 to 203 is not equal to a grating period pitch of another column of gratings thereof. For example, a grating period pitch between adjacent gratings in the gratings 201 is Λ1, a grating period pitch between adjacent gratings in the gratings 202 is Λ2, and a grating period pitch between adjacent gratings in the gratings 203 is Λ3.

A corresponding grating column directly below a corresponding ridge waveguide makes it possible to perform grating screening on light having a specified wavelength, so as to obtain a narrow linewidth wavelength with a narrower half-wave width. Based on calculation according to the following formula (1), a designed grating period pitch may be used to implement screening for the specified wavelength, where Λ is the foregoing grating period pitch, λ is the screening wavelength, and n is a refractive index of a material.

Λ=λ/2n formula (1)

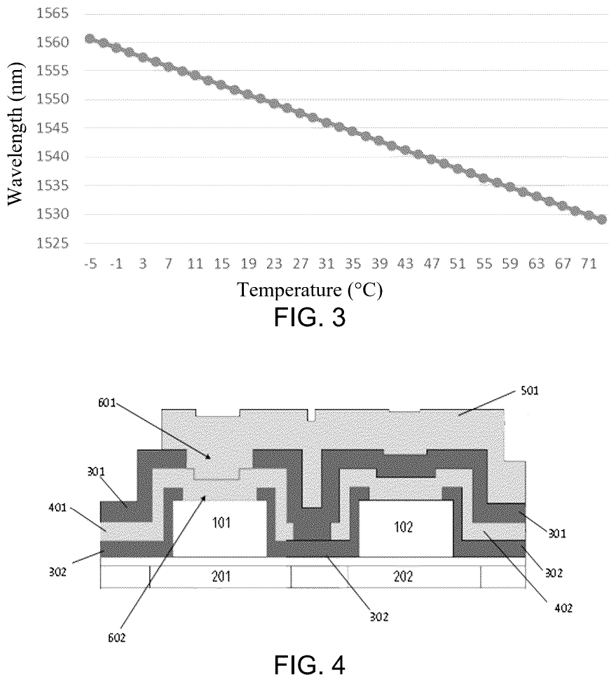

FIG. 3 is a diagram of a change curve of a lasing wavelength and a temperature according to an embodiment. Referring to FIG. 3, a horizontal coordinate represents a temperature, and a vertical coordinate represents a wavelength. Each temperature corresponds to one wavelength, and the wavelength may be a center wavelength of emitted light. In some embodiments, grating period pitches of the multiple columns of gratings are sequentially set based on a preset change curve of a lasing wavelength and a temperature. After a wavelength is selected from FIG. 3, a grating period pitch of a grating corresponding to wavelength screening for the wavelength can be calculated with reference to formula (1), so as to be suitable for the temperature-controlled lasing wavelength.

FIG. 4 is a schematic partial cross-sectional view of a chip. With reference to FIG. 4, the chip includes electrodes 400 that cover a ridge waveguide layer 100a, the ridge waveguide layer 100a has multiple ridge waveguides 100 (for example, a ridge waveguide 101 and a ridge waveguide 102), and the electrodes 400 can include an electrode 401 and an electrode 402. Electrode connection lines may include electrode connection lines 501. The ridge waveguide 101 is covered with the electrode 401, the ridge waveguide 102 is covered with the electrode 402, the electrodes 401 and 402 are covered with first insulating dielectric films 301, and the first insulating dielectric films 301 are provided with an electrode connection line 501. In this figure, the electrode connection line 501 is an electrode connection line corresponding to the electrode 401. Therefore, the first insulating dielectric film 301 defines a first opening 601 above the ridge waveguide 101, the electrode connection line 501 is connected to the electrode 401 through the first opening 601, and the electrode connection line 501 is not connected to the electrode 402. For the coverage of the electrode connection line 501, the first insulating dielectric film 301 defines no opening above the ridge waveguide 102, and therefore, the electrode connection line 501 is not connected to the electrode 402 corresponding to the ridge waveguide 102. Therefore, it is ensured that the electrode connection line 501 is insulated from the ridge waveguide 102, and can only control the ridge waveguide 101 independently. It should be known that although an electrode connection line corresponding to the electrode 402 corresponding to the ridge waveguide 102 and a first opening 601 provided in the first insulating dielectric film 301 above the ridge waveguide 102 are not shown in the figure, for the ridge waveguide 102 and other ridge waveguides, the first opening 601 is defined in the first insulating dielectric film 301 by using a method similar to that of the ridge waveguide 101, so that the electrode connection lines 500 corresponding to the ridge waveguides 100 are connected to the electrodes 400 corresponding to the ridge waveguides 100 in a one-to-one correspondence, so that each ridge waveguide 100 can be independently controlled. Details are not described herein again.

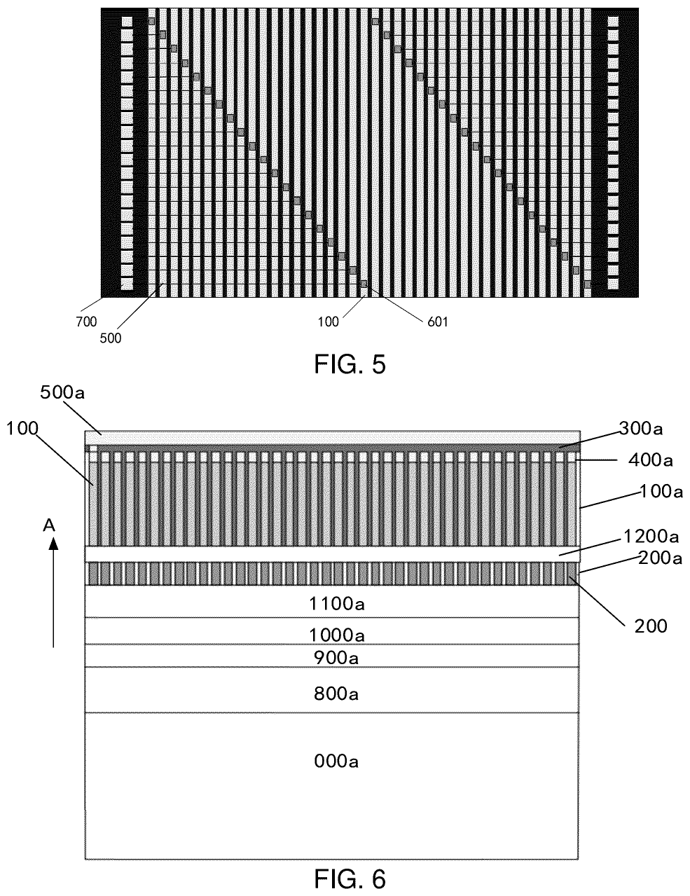

Referring to FIG. 5, in a specific implementation of this embodiment, a first opening 601 above a ridge waveguide 100 and a first opening 601 above an adjacent ridge waveguide 100 are staggered from each other. In some embodiments, first openings 601 of any two ridge waveguides 100 of the multiple ridge waveguides 100 are staggered from each other, so as to avoid a contact short circuit of electrode connection lines 500 therefor.

The chip further includes a second insulating dielectric film 302 disposed between a ridge waveguide 100 and an electrode 400. Referring to FIG. 4, a second insulating dielectric film 302 is disposed between the ridge waveguide 101 and the electrode 401, and a second opening 602 is defined above each ridge waveguide 101 on the second insulating dielectric film, such that the ridge waveguide 101 is partially connected to the electrode 401. A second insulating dielectric film 302 is disposed between the ridge waveguide 102 and the electrode 402, and a second opening is defined above the ridge waveguide 102, such that the ridge waveguide 102 is partially connected to the electrode 402.

Referring to FIG. 5, the photodiode chip includes multiple ridge waveguides 100. The chip further includes multiple pads 700, where the multiple pads 700 are in a one-to-one correspondence with the first openings 601 above the ridge waveguide layer, and each of the electrode connection lines 500 connects an electrode 400 (not shown in the figure) at a first opening 601 to a corresponding pad 700 through the first opening 601. Openings 600 include a first opening 601 and a second opening 602.

In some embodiments, according to actual production needs, a photodiode chip may include 40 ridge waveguides 100, and each ridge waveguide 100 may emit light having one wavelength. Correspondingly, there are 40 columns of gratings 200. Each ridge waveguide 100 corresponds to one column of gratings 200, one first opening 601, one second opening 602, one electrode 400, one electrode connection line 500, and one pad 700. Referring to FIG. 5, the first openings 601 corresponding to the ridge waveguide 100 are staggered, and therefore, corresponding electrode connection lines 500 do not intersect with each other, which better avoids mutual influence. It is avoided that the conduction of one electrode connection line 500 causes the other electrode connection lines 500 in contact with it to be forced to conduct electricity to cause a disorder in the emitted light.

FIG. 6 is a schematic cutaway view of a photodiode chip according to an embodiment. Referring to FIG. 6, the chip includes a grating layer 200a, a ridge waveguide layer 100a, an electrode layer 400a, an insulating dielectric film layer 300a, and an electrode connection line layer 500a. The chip further includes: a buffer layer 800a, a lower waveguide layer 900a, a quantum well layer 1000a, and an upper waveguide layer 1100a that are sequentially distributed from bottom to top above a substrate 000a and below the grating layer 200a, where the chip further includes a corrosion stop layer 1200a between the grating layer 200a and the ridge waveguide layer 100a. The grating layer 200a includes multiple columns of gratings 200, the ridge waveguide layer 100a includes multiple ridge waveguides 100, the electrode layer 400a includes electrodes 400 corresponding to the ridge waveguides 100, and the electrode connection line layer 500a includes electrode connection lines 500 corresponding to the electrodes 400.

A direction from bottom to top above the substrate 000a is direction A shown in FIG. 6.

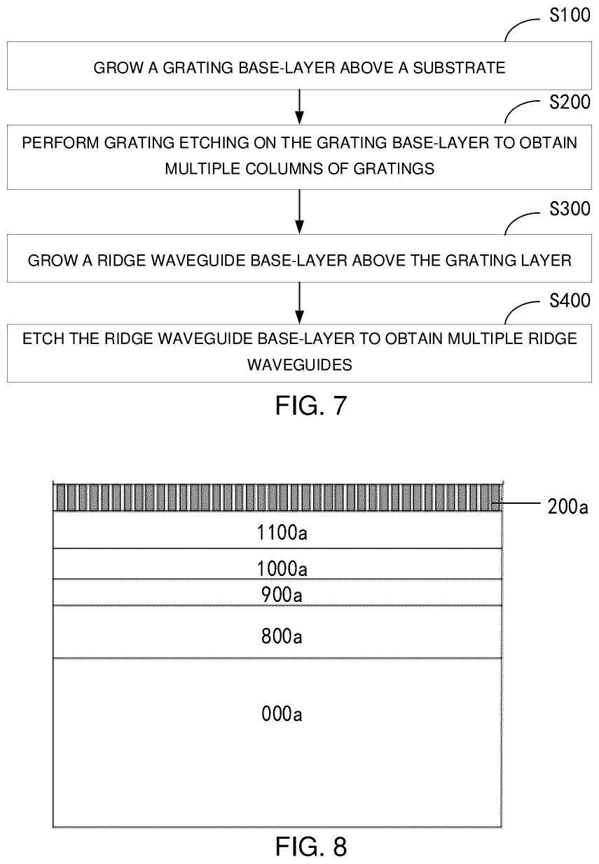

FIG. 7 is a schematic flowchart of a method for manufacturing a photodiode chip according to an embodiment. Referring to FIG. 1 to FIG. 15, the photodiode chip is an array laser chip for emitting laser light. The photodiode chip can emit laser light having different wavelengths at different temperatures. Referring to FIG. 7, the method includes the following.

S100: a grating base-layer is grown above a substrate 000a.

S200: grating etching is performed on the grating base-layer to obtain multiple columns of gratings 200, where the multiple columns of gratings 200 form a grating layer 200a.

S300: a ridge waveguide base-layer is grown above the grating layer.

S400: the ridge waveguide base-layer is etched to obtain multiple ridge waveguides 100.

In some embodiments, the substrate 000a is a clean single crystal plate having specific crystal faces and suitable electrical, optical, and mechanical properties and for growing epitaxial layers. The substrate 000a may be made of indium phosphide (InP). The grating base-layer may be made of an indium gallium arsenide phosphide (InGaAsP) grating material. In some embodiments, the grating material may have a refractive index of 3.5. Certainly, those skilled in the art may also select grating materials with other refractive indices, which are not limited thereto, and will not be enumerated herein. A grating period pitch of each grating 100 is a ratio of a corresponding screening wavelength to twice the refractive index of the grating material. For example, when the specified screening wavelength is 1550 nm and the refractive index n of the grating material InGaAsP is 3.5, a corresponding designed grating period Λ is 221.4 nm based on calculation according to formula (1).

In some embodiments, referring to FIG. 1 and FIG. 6, the multiple columns of gratings 200 (for example, gratings 201 and 202) form the grating layer 200a. The multiple columns of gratings can be made through etching on the grating base-layer by using electron beam lithography. Each column of gratings 200 are optical devices composed of a large number of parallel slits of equal width and equal pitch. The gratings 200 can be used for wavelength screening. After light having a specific spectrum width is screened by using the gratings 200, the spectrum width of the light may be narrowed, that is, light having some wavelengths is filtered out. Each column of gratings 200 are used to perform screening on light having a specific wavelength as a center wavelength, so that the screened light has a specific wavelength as a center wavelength and has a specific spectrum width.

In some embodiments, a corrosion stop layer 1200a and a positively doped top-layer 100b that are sequentially distributed from bottom to top are deposited and grown above the grating layer 200a by using a first growth method, where the positively doped top-layer 100b is the ridge waveguide base-layer.

In some embodiments, the first growth method is a metal-organic chemical vapor deposition (MOCVD) technology, and the corrosion stop layer 1200a may be an InGaAsP corrosion stop layer 1200a. The positively doped top-layer 100b may be an InP top-layer.

In some embodiments, a corrosion passivation film is grown on the positively doped top-layer 100b by using a second growth method, and the corrosion passivation film is etched by using an etching process to obtain the ridge waveguide layer 100a and an etching-stop dielectric film 400b that are sequentially distributed from bottom to top, where the ridge waveguide layer 100a includes multiple ridge waveguides 100.

The second growth method may be a plasma enhanced chemical vapor deposition (PECVD) method. The corrosion passivation film may be a SiO₂ passivation film. The corrosion passivation film may be etched by using a lithography wet etching process to obtain the ridge waveguide layer 100a and the etching-stop dielectric film 400b that are sequentially distributed from bottom to top.

In some embodiments, before S100, the method further includes the following. A buffer layer 800a, a lower waveguide layer 900a, a quantum well layer 1000a, and an upper waveguide layer 1100a that are sequentially distributed from bottom to top are deposited and grown above the substrate by the first growth method.

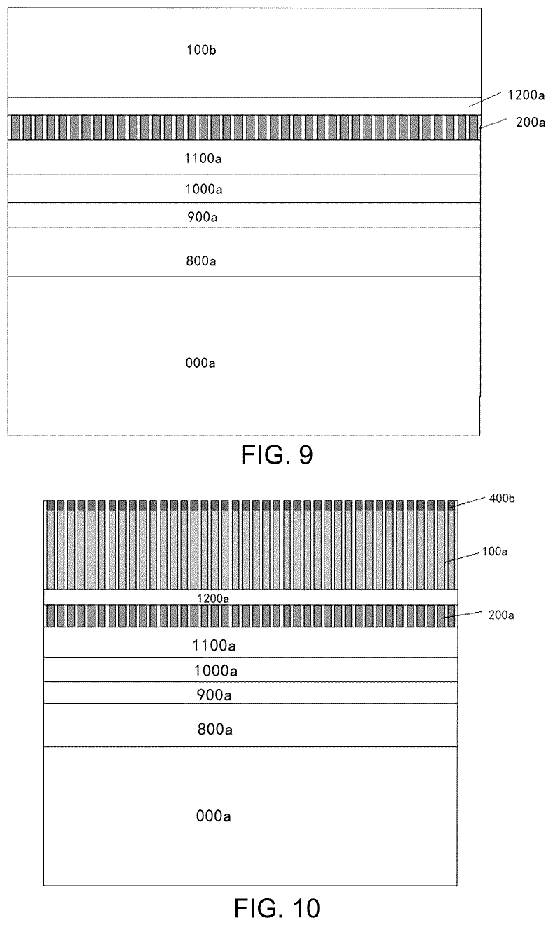

In some embodiments, FIG. 8 is an epitaxial cutaway view after a grating is manufactured according to an embodiment. Referring to FIG. 8, a buffer layer 800a, a lower waveguide layer 900a, a quantum well layer 1000a, an upper waveguide layer 1100a, and a grating layer 200a are sequentially included from bottom to top in a vertical direction of a substrate 000a.

In some embodiments, S100 includes the following. The grating base-layer is grown above the upper waveguide layer 1100a.

FIG. 9 is an epitaxial cutaway view after a corrosion stop layer and a positively doped top-layer are grown according to an embodiment. Referring to FIG. 9, a buffer layer 800a, a lower waveguide layer 900a, a quantum well layer 1000a, an upper waveguide layer 1100a, a grating layer 200a, a corrosion stop layer 1200a, and a positively doped top-layer 100b are sequentially included from bottom to top in a vertical direction of a substrate 000a.

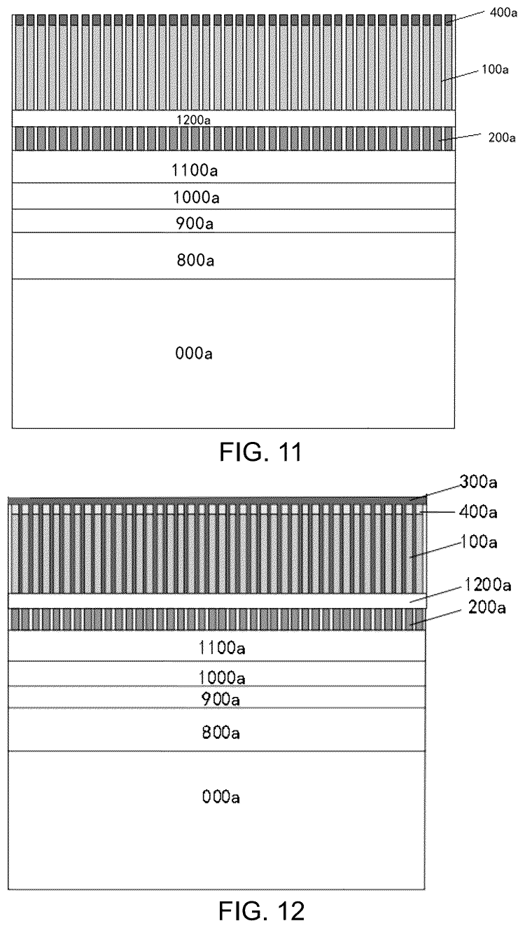

FIG. 10 is an epitaxial cutaway view after a ridge waveguide layer and an etching-stop dielectric film are obtained through etching according to an embodiment. Referring to FIG. 10, a buffer layer 800a, a lower waveguide layer 900a, a quantum well layer 1000a, an upper waveguide layer 1100a, a grating layer 200a, a corrosion stop layer 1200a, a ridge waveguide layer 100a, and an etching-stop dielectric film 400b are sequentially included from bottom to top in a vertical direction of a substrate 000a. The positively doped top-layer 100b in FIG. 9 is etched to obtain the ridge waveguide layer 100a and the etching-stop dielectric film 400b.

In some embodiments, after S400, the method further includes the following. The etching-stop dielectric film 400b is corroded to provide a second opening 602 above each ridge waveguide 100, and an electrode 400 is manufactured at a position above each ridge waveguide 100 to generate a semiconductor bar.

In some embodiments, a first electrode, a second electrode, and a third electrode distributed sequentially from bottom to top are manufactured above the ridge waveguide 100 by using a photoresist lift-off process, to generate the semiconductor bar, and the electrode 400 is in contact with the ridge waveguide 100 through the second opening 602. FIG. 11 is an epitaxial cutaway view after an electrode is manufactured. Referring to FIG. 11, a buffer layer 800a, a lower waveguide layer 900a, a quantum well layer 1000a, an upper waveguide layer 1100a, a grating layer 200a, a corrosion stop layer 1200a, a ridge waveguide layer 100a, and an electrode layer 400a are sequentially included from bottom to top in a vertical direction of a substrate 000a. The positively doped top-layer 100b in FIG. 9 is etched to obtain the ridge waveguide layer 100a and the electrode layer 400a. After the etching-stop dielectric film 400b in FIG. 10 is corroded, corresponding electrodes 400 are manufactured on the ridge waveguides 100 by using a photoresist lift-off process. The electrodes 400 include a first electrode, a second electrode, and a third electrode. Openings 600 include a second opening 602.

In some embodiments, the first electrode is a titanium electrode, the second electrode is a platinum electrode, and the third electrode is a gold electrode. The titanium electrode has better viscosity, the platinum electrode is used to isolate the titanium electrode from the gold electrode, and the gold electrode is easy to fuse with other metals and has good electrical conductivity.

The method further includes the following. An insulating dielectric film 300 is deposited and grown on the semiconductor bar by the second growth method, such that the insulating dielectric films 300 are grown between adjacent ridge waveguides 100 of the multiple ridge waveguides 100, between electrodes 400 corresponding to the adjacent ridge waveguides 100, and on the electrodes 400; a first opening 601 is defined in an insulating dielectric film 300 of an electrode 400 corresponding to each of the ridge waveguides 100; photoetching is performed at preset pad positions to obtain pads 700; and photoetching is performed between each of the pads 700 and a corresponding first opening 601 to obtain an electrode connection line 500.

In some embodiments, the semiconductor bar is a semiconductor laser bar. FIG. 12 is an epitaxial cutaway view after an insulating dielectric film is grown. Referring to FIG. 12, a buffer layer 800a, a lower waveguide layer 900a, a quantum well layer 1000a, an upper waveguide layer 1100a, a grating layer 200a, a corrosion stop layer 1200a, a ridge waveguide layer 100a, an electrode layer 400a, and an insulating dielectric film layer 300a are sequentially included from bottom to top in a vertical direction of a substrate 000a. The insulating dielectric film layer 300a is located between adjacent ridge waveguides 100, between adjacent electrodes 400 corresponding to the adjacent ridge waveguides 100, and on the electrodes 400.

The insulating dielectric film layer 300a includes a first insulating dielectric film 301 and a second insulating dielectric film 302. An insulating dielectric film 300 located on the electrodes 400 and between the adjacent electrodes 400 corresponding to the adjacent ridge waveguides 100 is the first insulating dielectric film 301, and an insulating dielectric film 300 located between the adjacent ridge waveguides 100 is the second insulating dielectric film 302.

The first opening 601 may be defined by using a photolithography etching process. Each pad 700 is connected to one electrode 400 through a first opening 601, and the electrode 400 is in contact with a corresponding ridge waveguide 100. The pad 700 is connected to an external power source, so that the pad 700 can perform energization control on the corresponding ridge waveguide 100 by using the electrode 400.

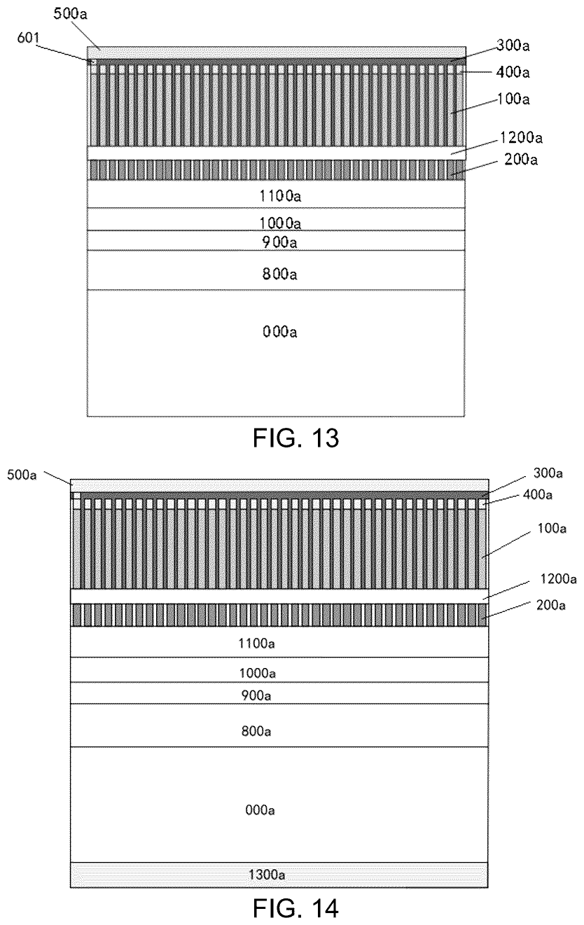

FIG. 13 is an epitaxial cutaway view after a first opening is defined for one ridge waveguide according to an embodiment. Referring to FIG. 13, a first opening 601 is an opening defined in an insulating dielectric film 300 of an electrode 400 corresponding to a ridge waveguide 100. In some embodiments, the first opening 601 can be defined by using a photolithography etching process, and the function of the first opening 601 is to connect the corresponding electrode 400 to an electrode connection line 500.

In some embodiments, the method further includes the following. The back of the substrate 000a is thinned to enable the semiconductor bar to reach a preset thickness, and the bar is polished; a negative electrode contact layer 1300a is evaporated on the back of the substrate 000a; rapid alloying is performed for preset duration at a preset temperature in a preset operating environment to form an ohmic contact; cleavage is performed on the semiconductor bar to obtain multiple photodiode chips; an antireflective film 1400a having a reflectivity of a first reflectivity is evaporated at a light-emitting end of each photodiode chip; a reflective film 1500a having a reflectivity of a second reflectivity is evaporated at the other end of the photodiode chip.

In some embodiments, the preset thickness may be 100 um, but is not limited thereto. On the back of the photodiode chip, that is, the back of the substrate, the negative electrode contact layer 1300a, that is, an N electrode, is evaporated. The negative electrode contact layer 1300a may be a nickel-germanium-gold (NiGeAu) negative electrode contact layer. The preset temperature may be 420 degrees Celsius, the preset operating environment may be an inert gas environment, the inert gas may be nitrogen, and the preset duration is 15 s, or may be any duration from 10 s to 30 s. The first reflectivity may be 5%, and the second reflectivity may be 98%.

FIG. 14 is an epitaxial cutaway view after a negative electrode contact layer is evaporated according to an embodiment. Referring to FIG. 14, a negative electrode contact layer 1300a is evaporated on the back of a substrate.

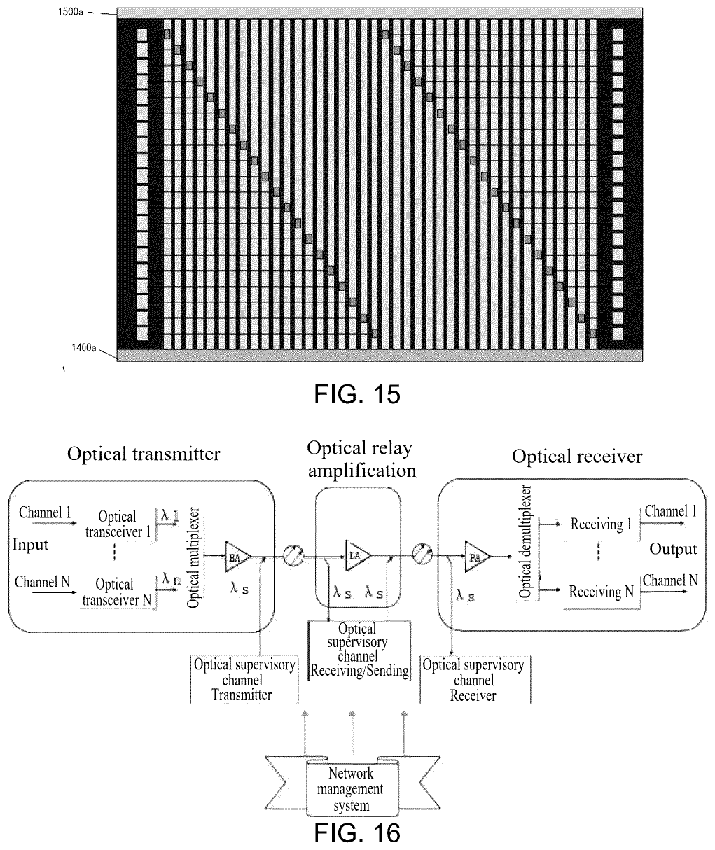

FIG. 15 is a front view of a chip after a reflective film and an antireflective film are evaporated according to an embodiment. Referring to FIG. 15, in two ends of the chip perpendicular to the ridge waveguide 100, an antireflective film is evaporated at one end to form an antireflective film 1400a, and this end is a light-emitting end of the chip; and a reflective film is evaporated at the other end to form a reflective film 1500a, and this end is a backlight end of the chip.

FIG. 16 is a structural block diagram of a dense wavelength division multiplexing (DWDM) transmission system according to an embodiment. Referring to FIG. 16, it can be learned from the diagram of the DWDM system that an optical transmitter in this system needs to provide light emitting source signals having multiple wavelengths of λ1 to λn. Usual typical wavelengths of the DWDM system are shown in Table 1. A total of 40 transmission wavelengths with a wavelength interval of 0.81 nm, which requires 40 light emitting sources in the optical transmitter of the system to generate optical signals having the 40 different transmission wavelengths respectively.

There are usually two types of light emitting sources for optical communication: an Fabry-Perot (FP) photodiode chip and a distributed feedback (DFB) photodiode chip. A half-wave width of a wavelength of a light wave signal generated by the FP photodiode chip is relatively wide, which is suitable for short-distance transmission. The DFB photodiode chip may generate, by using a wave selection function of the Bragg grating, light wave signals having a wavelength with a very narrow half-wave width, which can be applied to long-distance light wave signal transmission. In the DWDM system, since a wavelength spacing between adjacent channels is very narrow, it is only necessary to use DFB photodiode chips as light emitting sources. In an existing ridge waveguide DFB photodiode chip, a ridge waveguide formed by etching upper and lower electrodes of the chip energizes an active region of a quantum well of the chip to form ion inversion to generate emergent laser light. Then, the emergent laser light is screened for a specified emergent wavelength while passing through a grating layer, then is emitted after passing through a resonant cavity formed by the front and rear coatings of the chip, and finally, is emitted through a laser light source having a designed wavelength from the front of the chip. Therefore, the wavelength of the laser light emitted by the photodiode chip usually depends on the design of the quantum well of the chip, and a line width of the emergent wavelength mainly depends on the design of the grating of the chip and the length of the resonant cavity of the chip. The only writing method for a single DFB photodiode grating is usually to use a holographic projection etching writing method to make a grating of the same size on an entire wafer of the substrate. To provide light emitting sources with the 40 wavelengths shown in Table 1, the usual practice is to use 40 DFB photodiode discrete devices individually packaged into TO CAN.

TABLE 1
Typical operating wavelength of the DWDM system

| Serial No. | Center frequency (THz) | Wavelength (nm) |
|---|---|---|
| 1 | 192.1 | 1560.6 |
| 2 | 192.2 | 1559.79 |
| 3 | 192.3 | 1558.98 |
| 4 | 192.4 | 1558.17 |
| 5 | 192.5 | 1557.36 |
| 6 | 192.6 | 1556.55 |
| 7 | 192.7 | 1555.74 |
| 8 | 192.8 | 1554.93 |
| 9 | 192.9 | 1554.12 |
| 10 | 193 | 1553.31 |
| 11 | 193.1 | 1552.5 |
| 12 | 193.2 | 1551.69 |
| 13 | 193.3 | 1550.88 |
| 14 | 193.4 | 1550.07 |
| 15 | 193.5 | 1549.26 |
| 16 | 193.6 | 1548.45 |
| 17 | 193.7 | 1547.64 |
| 18 | 193.8 | 1546.83 |
| 19 | 193.9 | 1546.02 |
| 20 | 194 | 1545.21 |
| 21 | 194.1 | 1544.4 |
| 22 | 194.2 | 1543.59 |
| 23 | 194.3 | 1542.78 |
| 24 | 194.4 | 1541.97 |
| 25 | 194.5 | 1541.16 |
| 26 | 194.6 | 1540.35 |
| 27 | 194.7 | 1539.54 |
| 28 | 194.8 | 1538.73 |
| 29 | 194.9 | 1537.92 |
| 30 | 195 | 1537.11 |
| 31 | 195.1 | 1536.3 |
| 32 | 195.2 | 1535.49 |
| 33 | 195.3 | 1534.68 |
| 34 | 195.4 | 1533.87 |
| 35 | 195.5 | 1533.06 |
| 36 | 195.6 | 1532.25 |
| 37 | 195.7 | 1531.44 |
| 38 | 195.8 | 1530.63 |
| 39 | 195.9 | 1529.82 |
| 40 | 196 | 1529.01 |

Therefore, there are mainly several problems in the prior art as follows. 1. a large size, where 40 wavelengths mean that 40 different DFB photodiode chips and transistor outline (TO) devices are required to be packaged and coupled separately; 2. high costs, where because 40 single photodiode chips and TO devices need to be used, the production costs of the chip and the costs of TO packaging will be relatively expensive, and because the 40 single photodiode chips also need 40 separate coupling packages, the labor costs will be relatively expensive, and the process cycle time will be relatively long.

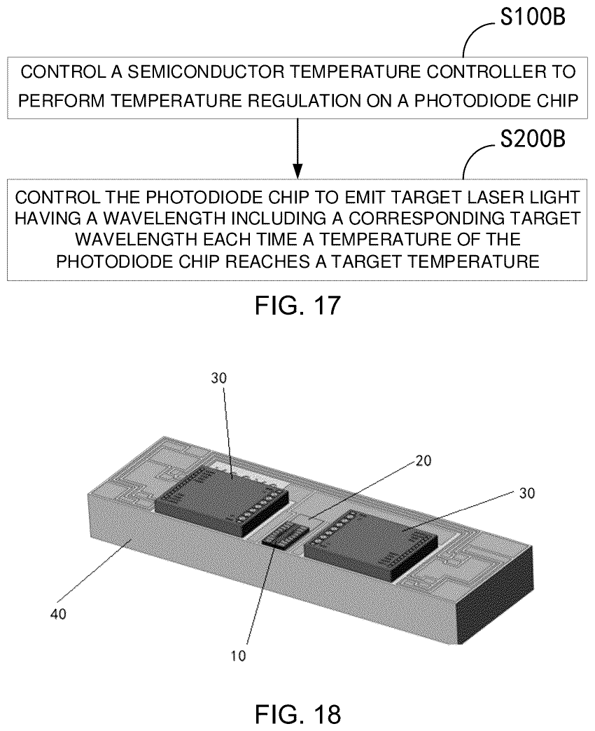

FIG. 17 is a schematic flowchart of a method for controlling a wavelength of a photodiode according to an embodiment. The method for controlling a wavelength of a photodiode is a laser light emitting method or a method for obtaining multiple types of laser light. The method is applied to a driver electronic chip. Referring to FIG. 17, the method includes the following.

S100B: a semiconductor temperature controller is controlled to regulate a temperature of a photodiode chip.

S200B: the photodiode chip is controlled to emit target laser light having a wavelength including a corresponding target wavelength each time the temperature of the photodiode chip reaches a target temperature.

In some embodiments, the target wavelength is related to the target temperature, and the target laser light has a spectrum width. A wavelength of laser light emitted by the photodiode chip is related to a temperature of the chip. The temperature of the photodiode chip is adjusted and controlled by the semiconductor temperature controller (e.g., thermoelectric cooler (TEC)), and the wavelength of the laser light emitted by the photodiode chip is selected so that the photodiode chip can emit laser light having a target wavelength. The same photodiode can emit laser light having different target wavelengths according to different temperatures. Therefore, only one photodiode is needed to implement the generation of different laser light, and the combined packaging of a large number of photodiode chips and TO devices is not required. The costs are lower.

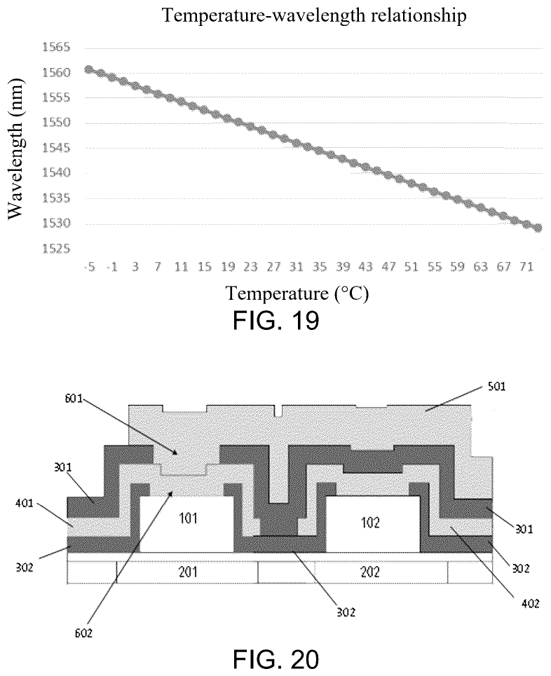

FIG. 19 is a diagram of a curve of a temperature of a photodiode chip and a lasing wavelength according to an embodiment. In this embodiment, the temperature of the photodiode chip has a linear relationship with the lasing wavelength. A lower temperature leads to a longer wavelength of emitted laser light, and a higher temperature leads to a shorter wavelength of emitted laser light.

In some embodiments, the temperature regulation is progressive temperature regulation corresponding to multiple different temperature regulation moments. In some embodiments, the progressive temperature regulation refers to continuous decreasing temperature control or continuous increasing temperature control. Each temperature regulation moment corresponds to one target temperature. One temperature may be set to be regulated at one moment, and a temperature is continuously regulated. For example, referring to FIG. 19, the temperature can be adjusted successively from the lowest temperature to the high temperature. At each temperature, the photodiode chip emits laser light having one wavelength. This makes temperature adjustment easier to control in an orderly manner.

In some embodiments, S100B includes the following. Different operating voltages are set for the semiconductor temperature controller at different temperature regulation moments, such that the semiconductor temperature controller regulates the temperature of the photodiode chip under different operating voltages.

In some embodiments, the driver electronic chip is connected to the semiconductor temperature controller for regulating a voltage of the semiconductor temperature controller, and the semiconductor temperature controller regulates the temperature according to a change of the voltage, so that the temperature of the photodiode chip changes accordingly.

In some embodiments, S200B includes the following. A ridge waveguide of the photodiode chip that corresponds to each target temperature is determined; and energization control is performed on a corresponding ridge waveguide at each moment, such that each ridge waveguide energizes a quantum well layer of the photodiode chip and emits a target laser light having a wavelength including a corresponding target wavelength.

In some embodiments, there are multiple ridge waveguides on the same photodiode chip, each ridge waveguide corresponds to a different wavelength, and laser light having a different wavelength corresponds to a different target temperature. Therefore, a target wavelength may be determined based on the target temperature, thereby determining a corresponding ridge waveguide.

After the ridge waveguide is energized, an active region of the quantum well layer can be energized by using the ridge waveguide to form ion inversion and generate emergent laser light. Each ridge waveguide has a different energization effect on the quantum well layer, and therefore, a wavelength of corresponding emitted laser light is also different.

In some embodiments, a number of driver electronic chips in a photodiode can be selected according to the actual situation, for example: two driver electronic chips can be provided.

In some embodiments, the ridge waveguide of the photodiode chip that corresponds to each target temperature is determined as follows. The corresponding target wavelength is determined based on the target temperature; and the corresponding ridge waveguide of the photodiode chip is determined based on the target wavelength.

In some embodiments, laser light having different wavelengths is emitted by using corresponding ridge waveguides on photodiode chips at different target temperatures. Therefore, a target wavelength may be determined based on a target temperature, thereby determining a corresponding ridge waveguide.

In some embodiments, each ridge waveguide of the photodiode chip defines an opening, the photodiode chip further includes pads, electrode connection lines, and electrodes that each are in a one-to-one correspondence with each opening, and each of the pads is connected to the corresponding ridge waveguide by using the corresponding electrode connection line passing through the corresponding opening.

In some embodiments, openings are defined above each ridge waveguide of the photodiode chip. The openings include a first opening and a second opening, and correspond to one pad, one electrode connection line, and one electrode. The pad is connected to a driver electronic chip, the driver electronic chip is connected to or in contact with the electrode through the pad, the electrode connection line, and through the first opening sequentially, and the electrode is connected to or in contact with the ridge waveguide through the second opening.

In some embodiments, the energization control is performed on the corresponding ridge waveguide at each moment as follows. At each moment, energization driving is performed on the pad connected to the corresponding ridge waveguide, such that energization control is performed on the corresponding ridge waveguide by using the pad.

In some embodiments, the pad is in contact with or connected to the ridge waveguide through the electrode connection line, the first opening, the electrode, and the second opening sequentially. The driver electronic chip is connected to the pad, and after the driver electronic chip is driven, the corresponding ridge waveguide can be energized by using the pad connected to the driver electronic chip. After the ridge waveguide is energized, the ridge waveguide acts on the quantum well layer, so that the quantum well layer emits laser light having a target wavelength.

In some embodiments, any two pads are not in contact, any two electrode connection lines are not in contact, electrodes corresponding to any two ridge waveguides are not in contact, and any two ridge waveguides are not in contact, so that when one ridge waveguide is energized, other ridge waveguides are not affected, and then independent energization control is performed on each ridge waveguide.

In some embodiments, the method further includes the following. A corresponding grating on the photodiode chip is determined based on a ridge waveguide corresponding to the target wavelength, the corresponding grating is enabled to perform grating screening on target laser light corresponding to the target temperature to obtain corresponding laser light having a narrow spectrum width, and the laser light having a narrow spectrum width is used as the target laser light corresponding to the target temperature.

In some embodiments, target laser light having each target wavelength and emitted at each target temperature has a specific spectrum width, that is, each type of target laser light actually contains laser light having more than one wavelength, and there is laser light having other wavelengths at two ends of the laser light having the target wavelength. In order to make a spectrum width of the target laser light narrower, it is necessary to perform grating screening on the target laser light. Through gratings, laser light having wavelengths that differ from the target wavelength beyond a preset range is filtered out, and only laser light having wavelengths that differ from the target wavelength within the preset range is left as the target laser light obtained after the final grating screening.

In some embodiments, the corresponding grating is enabled to perform grating screening on target laser light corresponding to a target temperature to obtain the corresponding laser light having the narrow spectrum width as follows. The corresponding grating is enabled to perform total reflection on the target laser light corresponding to the target temperature through a rear edge of the grating, and to perform semi-transmission and semi-reflection on the target laser light through a front edge of the grating, such that carriers of the target laser light oscillate in the grating to obtain the corresponding laser light having a narrow spectrum width.

In some embodiments, a photodiode is provided, and the photodiode includes a photodiode chip, a semiconductor temperature controller, and a driver electronic chip. The semiconductor temperature controller is located on one side of the photodiode chip, and the photodiode is configured to emit laser light having different wavelengths according to any of the methods described above.

In some embodiments, the photodiode chip includes a quantum well layer and multiple ridge waveguides.

In some embodiments, the photodiode chip further includes multiple columns of gratings, each of the ridge waveguides corresponds to one column of gratings in the multiple columns of gratings below, and at least two columns of gratings of the multiple columns of gratings have different grating period pitches.

In some embodiments, a grating cavity of the photodiode chip has a length greater than 2 mm.

In some embodiments, a grating cavity on the photodiode chip has a length greater than 2 mm, so that two adjacent wavelengths do not overlap, and laser light having a narrow spectrum width as narrow as possible is obtained.

In some embodiments, the grating is grown under the corresponding ridge waveguide by using electron beam lithography or holography.

In some embodiments, the photodiode chip further includes multiple pads, multiple electrode connection lines, and multiple electrodes, and one pad is connected to or in contact with a corresponding electrode by using a corresponding electrode connection line, and the electrode is connected to or in contact with a corresponding ridge waveguide.

Referring to FIG. 18 to FIG. 23, the photodiode includes a photodiode chip 10, a semiconductor temperature controller 20, a driver electronic chip 30, and a ceramic carrier 40, and the photodiode chip 10, the semiconductor temperature controller 20, and the driver electronic chip 30 are all arranged on the ceramic carrier 40. The semiconductor temperature controller 20 is located on one side of the photodiode chip 10 and configured to regulate a temperature of the photodiode chip 10 to a target temperature, and the driver electronic chip 30 is configured to perform energization control on the photodiode chip 10 that is at the target temperature, such that the photodiode chip 10 at the target temperature emits target laser light having a wavelength including a corresponding target wavelength, where the target wavelength is related to the target temperature, and the target laser light has a spectrum width.

In some embodiments, a wavelength of laser light emitted by the photodiode chip 10 is related to a temperature of the chip. The temperature of the photodiode chip 10 is adjusted and controlled by the semiconductor temperature controller 20 (e.g., TEC), and the wavelength of the laser light emitted by the photodiode chip 10 is selected so that the photodiode chip 10 can emit laser light having a target wavelength. The same photodiode 10 can emit laser light having different target wavelengths according to different temperatures. Therefore, only one photodiode 10 is needed to implement the generation of different laser light, and the combined packaging of a large number of photodiode chips and TO devices is not required. The costs are lower.

In some embodiments, the photodiode chip 10 includes a quantum well layer 1000a and multiple ridge waveguides 100, and the driver electronic chip 30 performs energization control on a ridge waveguide 100 corresponding to the target temperature, such that the quantum well layer 1000a is energized by the corresponding ridge waveguide 100, to emit target laser light having a wavelength including a corresponding target wavelength.

In some embodiments, there are multiple ridge waveguides 100 on the same photodiode chip 10, each ridge waveguide 100 corresponds to a different wavelength, and laser light having a different wavelength corresponds to a different target temperature. Therefore, a target wavelength may be determined based on the target temperature, thereby determining a corresponding ridge waveguide 100.

After the ridge waveguide 100 is energized, an active region of the quantum well layer 1000a can be energized by using the ridge waveguide 100 to form ion inversion and generate emergent laser light. Each ridge waveguide 100 has a different energization effect on the quantum well layer 1000a, and therefore, a target wavelength of corresponding emitted target laser light is also different.

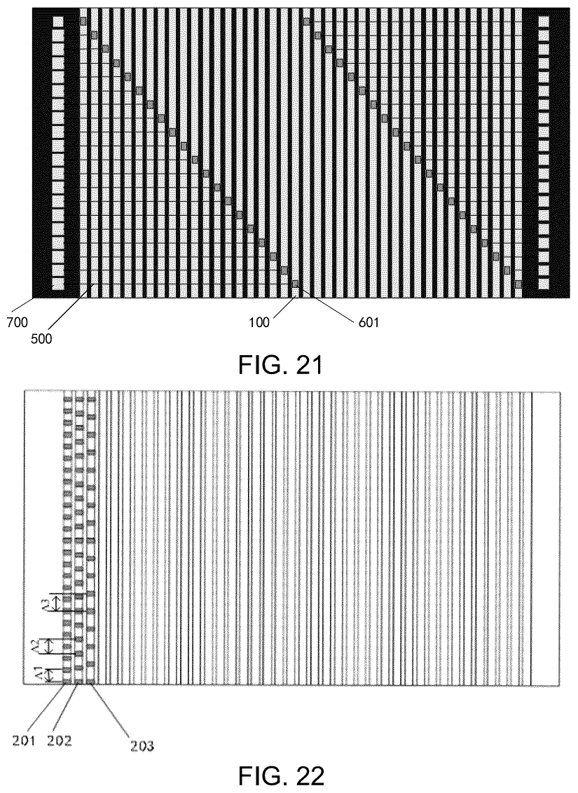

Referring to FIG. 21, in some embodiments, the photodiode chip 10 further includes multiple pads 700, electrode connection lines 500, and electrodes 400 that are in a one-to-one correspondence with each other, each of the pads 700 is connected to the corresponding ridge waveguide 100 by using the corresponding electrode connection line 500, and the driver electronic chip 30 performs energization control on a corresponding ridge waveguide 100 by sequentially using the corresponding pad 700, the corresponding electrode connection line 500, and the corresponding electrode 400 that are in a one-to-one correspondence with each other.

In some embodiments, the driver electronic chip 30 is connected to the pad 700, and after the driver electronic chip 30 is driven, the corresponding ridge waveguide 100 can be energized by using the pad 700 connected to the driver electronic chip by sequentially using the electrode connection line 500 and the corresponding electrode. After the ridge waveguide 100 is energized, the ridge waveguide acts on the quantum well layer, so that the quantum well layer 1000a emits laser light having a target wavelength.

With reference to FIG. 20, the photodiode chip 10 includes electrodes 400 that cover a ridge waveguide layer 100a, the ridge waveguide layer 100a has multiple ridge waveguides 100 (for example, a ridge waveguide 101 and a ridge waveguide 102), and the electrodes 400 include an electrode 401 and an electrode 402. Electrode connection lines 500 include electrode connection lines 501. The ridge waveguide 101 is covered with the electrode 401, the ridge waveguide 102 is covered with the electrode 402, the electrodes 401 and 402 are covered with first insulating dielectric films 301, and the first insulating dielectric films 301 are provided with an electrode connection line 501. In this figure, the electrode connection line 501 is an electrode connection line 500 corresponding to the electrode 401. Therefore, the first insulating dielectric film 301 defines a first opening 601 above the ridge waveguide 101, the electrode connection line 501 passes through the first opening 601 to be connected to the electrode 401, and the electrode connection line 501 is not connected to the electrode 402. For the coverage of the electrode connection line 501, the first insulating dielectric film 301 defines no opening above the ridge waveguide 102, and therefore, the electrode connection line 501 is not connected to the electrode 402 corresponding to the ridge waveguide 102. Therefore, it is ensured that the electrode connection line 501 is insulated from the ridge waveguide 102, and can only control the ridge waveguide 101 independently. It should be known that although an electrode connection line corresponding to the electrode 402 corresponding to the ridge waveguide 102 and a first opening 601 defined in the first insulating dielectric film 301 above the ridge waveguide 102 are not shown in the figure, for the ridge waveguide 102 and other ridge waveguides, the first opening 601 is defined in the first insulating dielectric film 301 by using a method similar to that of the ridge waveguide 101, so that the electrode connection lines 500 corresponding to the ridge waveguides 100 are connected to the electrodes 400 corresponding to the ridge waveguides 100 in a one-to-one correspondence, so that each ridge waveguide 100 can be independently controlled. Details are not described herein again.

In an implementation of this embodiment, a first opening 601 above a ridge waveguide 100 and a first opening 601 above an adjacent ridge waveguide 100 are staggered from each other. In some embodiments, first openings 601 of any two ridge waveguides 100 of the multiple ridge waveguides 100 are staggered from each other, so as to avoid a contact short circuit of electrode connection lines 500 therefor.

The photodiode chip further includes a second insulating dielectric film 302 disposed between a ridge waveguide 100 and an electrode 400. Referring to FIG. 18, a second insulating dielectric film 302 is disposed between the ridge waveguide 101 and the electrode 401, and a second opening 602 is defined above each ridge waveguide 101 on the second insulating dielectric film, such that the ridge waveguide 101 is partially connected to the electrode 401. A second insulating dielectric film 302 is disposed between the ridge waveguide 102 and the electrode 402, and a second opening is defined above the ridge waveguide 102, such that the ridge waveguide 102 is partially connected to the electrode 402.

The photodiode chip includes multiple ridge waveguides 100. The chip further includes multiple pads 700, where the multiple pads 700 are in a one-to-one correspondence with the first openings 601 above the ridge waveguide layer, and each of the electrode connection lines 500 connects an electrode 400 (not shown in the figure) at a first opening 601 to a corresponding pad 700 through the first opening 601. Openings 600 include a first opening 601 and a second opening 602.

Due to a stop effect of the insulating dielectric film, ridge waveguides 100 do not interfere with each other. When energization control is performed on a specific ridge waveguide 100, the insulating dielectric film prevents other ridge waveguides 100 from communicating with corresponding pads 700. Therefore, interference to the other ridge waveguides 100 is avoided, and independent energization control is performed on each ridge waveguide 100.

In some embodiments, the driver electronic chip 30 is connected to the semiconductor temperature controller 20, and the driver electronic chip 30 sets different voltages for the semiconductor temperature controller 20, such that the semiconductor temperature controller 20 regulates different temperatures for the photodiode chip 10.

In some embodiments, the photodiode chip 10 further includes multiple columns of gratings 200, each of the ridge waveguides 100 corresponds to one column of gratings 200 in the multiple columns of gratings 200, and a corresponding grating 200 is configured to perform grating screening on target laser light corresponding to the corresponding ridge waveguide 100, such that a spectrum width of the corresponding target laser light reaches a target spectrum width.

In some embodiments, target laser light having each target wavelength and emitted at each target temperature has a specific spectrum width, that is, each type of target laser light actually contains laser light having more than one wavelength, and there is laser light having other wavelengths at two ends of the laser light having the target wavelength. In order to make a spectrum width of the target laser light narrower, it is necessary to perform grating screening on the target laser light. Through gratings 200, laser light having wavelengths that differ from the target wavelength beyond a preset range is filtered out, and only laser light having wavelengths that differ from the target wavelength within the preset range is left as the target laser light obtained after the final grating screening.

In some embodiments, a grating cavity of the photodiode chip 10 has a length greater than 2 mm.

In some embodiments, a grating cavity on the photodiode chip 10 has a length greater than 2 mm, so that two adjacent wavelengths do not overlap, and laser light having a narrow spectrum width as narrow as possible is obtained.

In some embodiments, the grating 200 is grown under the corresponding ridge waveguide 100 by using electron beam lithography or holography.

In some embodiments, a rear edge of the grating 200 is configured to perform total reflection, and a front edge of the grating 200 is configured to perform semi-transmission and semi-reflection.

In some embodiments, target laser light corresponding to each target temperature is totally reflected through a rear edge of a corresponding grating 200, and then is semi-transmitted and semi-reflected through a front edge of the grating 200, such that carriers of the target laser light oscillate in the grating to obtain the corresponding laser light having a narrow spectrum width.

In some embodiments, the grating 200 is made of an InGaAsP grating material, and a grating period pitch of each column of gratings 200 is a ratio of a corresponding target wavelength to twice a refractive index of the grating material.

Referring to FIG. 22, the grating layer 200a includes multiple columns of gratings 200 (for example, gratings 201, gratings 202, and gratings 203), and a grating period pitch A of one column of gratings of the gratings 201 to 203 is not equal to a grating period pitch of another column of gratings thereof. For example, a grating period pitch between adjacent gratings in the gratings 201 is Λ1, a grating period pitch between adjacent gratings in the gratings 202 is Λ2, and a grating period pitch between adjacent gratings in the gratings 203 is Λ3.

A corresponding grating 200 directly below a corresponding ridge waveguide 100 makes it possible to perform grating screening on light having a specified wavelength, so as to obtain a narrow linewidth wavelength with a narrower half-wave width. Based on calculation according to the following formula (1), a designed grating period pitch may be used to implement screening for the specified wavelength, where Λ is the foregoing grating period pitch, λ is the screening wavelength, and n is a refractive index of a material.

Λ=λ/2n formula (1)

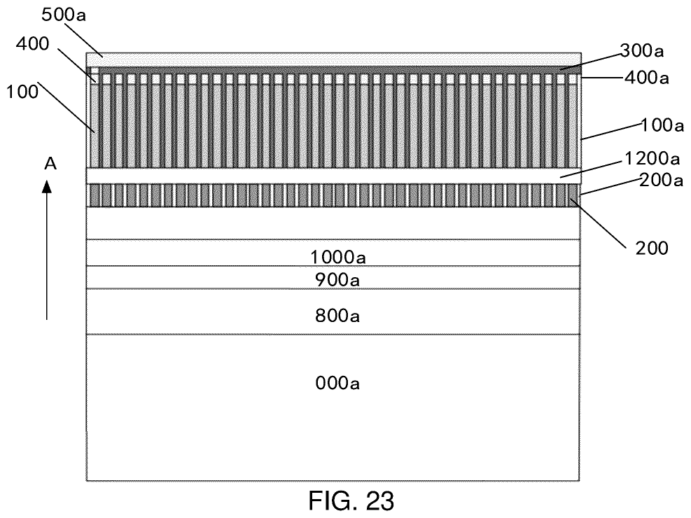

In some embodiments, multiple ridge waveguides 100 form a ridge waveguide layer 100a, and multiple columns of gratings 200 form a grating layer 200a. Referring to FIG. 23, the photodiode chip further includes: a buffer layer 800a, a lower waveguide layer 900a, a quantum well layer 1000a, and an upper waveguide layer 1100a that are sequentially distributed from bottom to top above a substrate 000a and below the grating layer 200a, where the photodiode chip further includes a corrosion stop layer 1200a between the grating layer 200a and the ridge waveguide layer 100a. A direction from bottom to top above the substrate 000a is shown as direction A in FIG. 20. The insulating dielectric film layer 300a is located between adjacent ridge waveguides 100, between adjacent electrodes 400 corresponding to the adjacent ridge waveguides 100, and on the electrodes 400. An electrode layer 400a covers the ridge waveguide layer 100a, and an electrode connection line layer 500a is located on the insulating dielectric film layer 300a.

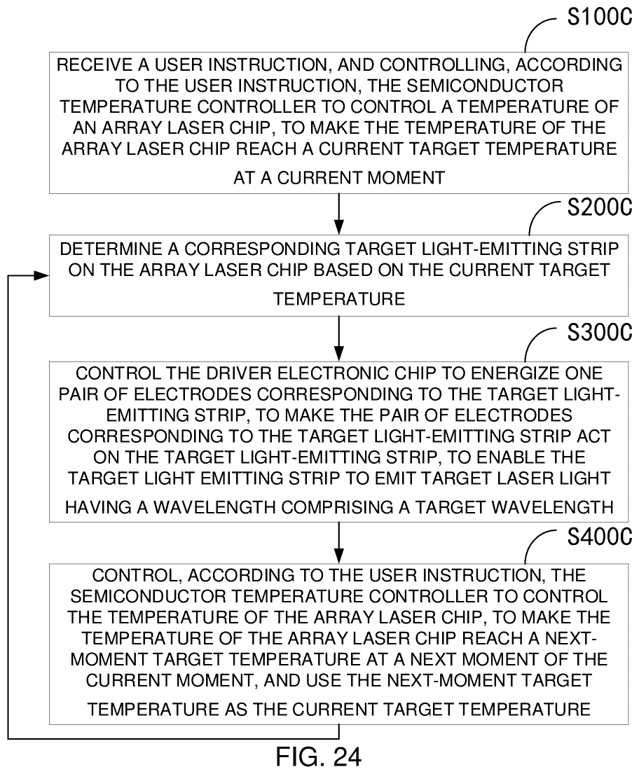

FIG. 24 is a schematic flowchart of a method for controlling a wavelength of a photodiode according to an embodiment. Referring to FIG. 24, the method includes the following.

S100C: a user instruction is received, and the semiconductor temperature controller is controlled, according to the user instruction, to control a temperature of the photodiode chip, such that the temperature of the photodiode chip reaches a current target temperature at a current moment.

S200C: a corresponding target light-emitting strip on the photodiode chip is determined based on the current target temperature.

S300C: the driver electronic chip is controlled to energize one pair of electrodes corresponding to the target light-emitting strip, to make the pair of electrodes corresponding to the target light-emitting strip act on the target light-emitting strip, to enable the target light-emitting strip to emit target laser light having a wavelength including a target wavelength.

S400C: the semiconductor temperature controller is controlled, according to the user instruction, to control the temperature of the photodiode chip, to make the temperature of the photodiode chip reach a next-moment target temperature at a next moment of the current moment, and by using the next-moment target temperature as the current target temperature, S200C is performed in a loop until all target laser light having different target wavelengths are emitted.

In some embodiments, multiple light-emitting strips and multiple pairs of electrodes are provided on one photodiode chip, each light-emitting strip may correspond to one pair of electrodes, and each light-emitting strip may emit target laser light having a wavelength including a corresponding target wavelength. Each type of target laser light has a spectrum width, that is, each type of target laser light actually contains laser light corresponding to more than the target wavelength, and there is laser light having other wavelengths at two ends of the laser light having the target wavelength. The semiconductor temperature controller is configured to control the temperature of the photodiode chip, a wavelength of laser light emitted by the photodiode chip is related to the temperature of the chip, and each target temperature corresponds to one type of target laser light. Each pair of electrodes includes a positive electrode and a negative electrode. The driver electronic chip is configured to energize one pair of electrodes connected to a target light-emitting strip, and energize the target light-emitting strip by using the electrodes, so as to enable the target light-emitting strip to emit target laser light having a wavelength including a target wavelength.

“Until all target laser light having different target wavelengths are emitted” means that target laser light required is emitted according to the needs of actual application scenarios.

In some embodiments, after S300C, the method further includes the following. The photodiode chip is controlled to perform wavelength screening on the target laser light, to make a spectrum width of the target laser light reach a preset spectrum width.

In some embodiments, the target laser light has a spectrum width. In order to make the spectrum width of the target laser light narrower, it is necessary to perform wavelength screening on the target laser light. Laser light having wavelengths that differ from the target wavelength beyond a preset range is filtered out, and only laser light having wavelengths that differ from the target wavelength within the preset range is left as the target laser light obtained after the final wavelength screening.

In some embodiments, S200C includes the following. A light-emitting strip corresponding to the current target temperature is searched for in a preset comparison list, and the found light-emitting strip is used as the target light-emitting strip.

In some embodiments, S300C includes the following. The driver electronic chip is controlled to energize the pair of electrodes corresponding to the target light-emitting strip, to make the pair of electrodes corresponding to the target light-emitting strip perform energization modulation on a quantum well layer of the target light-emitting strip by using a ridge waveguide on the target light-emitting strip, to enable the target laser light having the wavelength including the target wavelength to be emitted from the target light-emitting strip.

In some embodiments, after the ridge waveguide is energized, an active region of the quantum well layer can be energized by using the ridge waveguide to form ion inversion and generate emergent laser light. Each ridge waveguide has a different energization effect on the quantum well layer, and therefore, a wavelength of corresponding emitted laser light is also different.

In some embodiments, the photodiode chip is controlled to perform the wavelength screening on the target laser light, to make the spectrum width of the target laser light reach the preset spectrum width as follows. A grating corresponding to a ridge waveguide on the target light-emitting strip is controlled to perform the grating screening on the target laser light, to make the spectrum width of the target laser light after the grating screening reaches the preset spectrum width.

In some embodiments, each photodiode chip includes multiple ridge waveguides and multiple corresponding gratings, each grating is used to perform screening on light having a specific wavelength as a center wavelength, so that the screened light has a specific wavelength as a center wavelength and has a specific spectrum width. The center wavelength is a target wavelength of target laser light. Target laser light is emitted by using a ridge waveguide, and then a grating corresponding to the ridge waveguide is used for grating screening, and a spectrum width of the finally emitted laser light may be narrowed. That is, only laser light having wavelengths that differ from the target wavelength within the preset range is left.

In some embodiments, the grating corresponding to a ridge waveguide on the target light-emitting strip is controlled to perform the grating screening on the target laser light as follows. The grating corresponding to the ridge waveguide on the target light-emitting strip is controlled to perform total reflection on the target laser light through a rear edge of the grating, and to perform semi-transmission and semi-reflection on the target laser light through a front edge of the grating, to make carriers of the target laser light oscillate in the grating to obtain laser light having a specific wavelength.

In some embodiments, the grating is formed under the corresponding ridge waveguide by using electron beam lithography.

In some embodiments, a grating cavity on the photodiode chip has a length greater than 2 mm. For example, the length may be 3 mm.

In some embodiments, a grating cavity on the photodiode chip has a length greater than 2 mm, so that two adjacent wavelengths do not overlap, and laser light having a narrow spectrum width as narrow as possible is obtained.

In some embodiments, 12 or 14 light-emitting strips are disposed on the photodiode chip.

Each light-emitting strip may emit one type of target laser light having a target wavelength as a center wavelength. 12 light-emitting strips may emit 12 types of target laser light having different target wavelengths as center wavelengths. In actual application scenarios, different target laser light can be emitted by adjusting the temperature of the photodiode chip according to actual needs, and it is not necessary to use all the light-emitting strips.

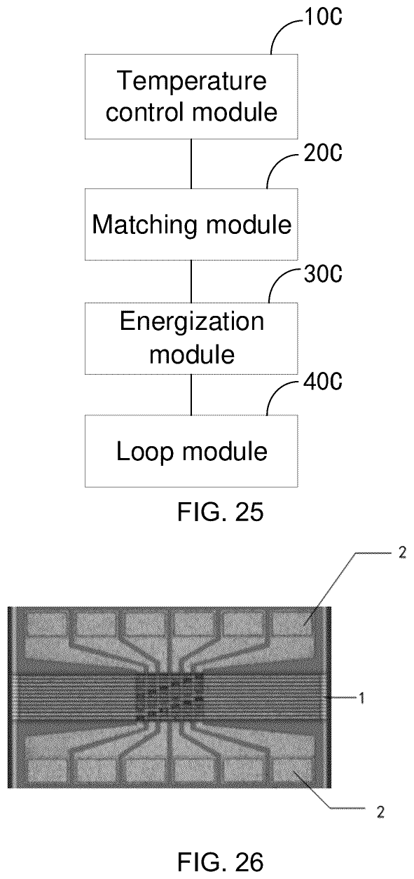

FIG. 25 is a structural block diagram of an apparatus for controlling a wavelength of a photodiode according to an embodiment. Referring to FIG. 25, the photodiode chip is provided with multiple light-emitting strips and multiple pairs of electrodes, each light-emitting strip corresponds to one pair of electrodes, and the apparatus includes a temperature control module 10C, a matching module 20C, an energization module 30C, and a loop module 40C. The temperature control module 10C is configured to receive a user instruction, and control, according to the user instruction, a semiconductor temperature controller to control a temperature of the photodiode chip, to make the temperature of the photodiode chip reach a current target temperature at a current moment. The matching module 20C configured to determine a corresponding target light-emitting strip on the photodiode chip based on the current target temperature. The energization module 30C is configured to control the driver electronic chip to energize one pair of electrodes corresponding to the target light-emitting strip, to make the pair of electrodes corresponding to the target light-emitting strip act on the target light-emitting strip, to enable the target light-emitting strip to emit target laser light having a wavelength including a target wavelength, the target laser light having a spectrum width. The loop module 40C is configured to control, according to the user instruction, the semiconductor temperature controller to control the temperature of the photodiode chip, to make the temperature of the photodiode chip reach a next-moment target temperature at a next moment of the current moment, and perform, by using the next-moment target temperature as the current target temperature, the determining the corresponding target light-emitting strip on the photodiode chip based on the current target temperature, until all target laser light having different target wavelengths are emitted.

In some embodiments, the apparatus further includes a screening module. The screen module is configured to control the photodiode chip to perform wavelength screening on the target laser light, such that a spectrum width of the target laser light reaches a preset spectrum width.

In some embodiments, a grating corresponding to a ridge waveguide on the target light-emitting strip is used to perform grating screening on the target laser light, such that a spectrum width of the target laser light obtained after the grating screening reaches a preset spectrum width. In some embodiments, the target laser light is totally reflected through a rear edge of the grating corresponding to the ridge waveguide on the target light-emitting strip, and is then partially transmitted and partially reflected through a front edge of the grating, such that carriers of the target laser light oscillate in the grating to obtain laser light having a specific wavelength.

In some embodiments, the matching module 20C is configured to search for a light-emitting strip corresponding to the current target temperature in a preset comparison list, and use the found light-emitting strip as the target light-emitting strip.

In some embodiments, the energization module 30C is configured to control the driver electronic chip to energize the pair of electrodes corresponding to the target light-emitting strip, such that the pair of electrodes corresponding to the target light-emitting strip performs energization modulation on a quantum well layer of the target light-emitting strip by using a ridge waveguide on the target light-emitting strip, so as to enable the target laser light having the wavelength including the target wavelength to be emitted from the target light-emitting strip.

FIG. 26 is a front top view of a photodiode chip according to an embodiment. Referring to FIG. 26, from the front of the photodiode chip, it can be learned that positive electrodes 2 are distributed on both sides of the photodiode chip, and negative electrodes of the photodiode chip are distributed on the back of the chip (not shown in the figure), and light-emitting strips are distributed in the middle. Each light-emitting strip 1 corresponds to one pair including a positive electrode and a negative electrode.

In some embodiments, a computer-readable storage medium is provided, having stored thereon a computer program. When the computer program is executed by a processor, the processor performs the following steps: receiving a user instruction, and controlling, according to the user instruction, the semiconductor temperature controller to control a temperature of the photodiode chip, such that the temperature of the photodiode chip reaches a current target temperature at a current moment; determining a corresponding target light-emitting strip on the photodiode chip based on the current target temperature; controlling the driver electronic chip to energize one pair of electrodes corresponding to the target light-emitting strip, such that the pair of electrodes corresponding to the target light-emitting strip acts on the target light-emitting strip, so as to enable the target light-emitting strip to emit target laser light having a wavelength including a target wavelength, the target laser light having a spectrum width; and controlling, according to the user instruction, the semiconductor temperature controller to control the temperature of the photodiode chip, such that the temperature of the photodiode chip reaches a next-moment target temperature at a next moment of the current moment, and performing, by using the next-moment target temperature as the current target temperature, the determining a corresponding target light-emitting strip on the photodiode chip based on the current target temperature, until all target laser light having different target wavelengths are emitted.

In some embodiments, a computer device is provided, including a memory, a processor, and a computer program stored on the memory and operable on the processor. When the processor executes the program, the following steps are performed: receiving a user instruction, and controlling, according to the user instruction, the semiconductor temperature controller to control a temperature of the photodiode chip, such that the temperature of the photodiode chip reaches a current target temperature at a current moment; determining a corresponding target light-emitting strip on the photodiode chip based on the current target temperature; controlling the driver electronic chip to energize one pair of electrodes corresponding to the target light-emitting strip, such that the pair of electrodes corresponding to the target light-emitting strip acts on the target light-emitting strip, so as to enable the target light-emitting strip to emit target laser light having a wavelength including a target wavelength, the target laser light having a spectrum width; and controlling, according to the user instruction, the semiconductor temperature controller to control the temperature of the photodiode chip, such that the temperature of the photodiode chip reaches a next-moment target temperature at a next moment of the current moment, and performing, by using the next-moment target temperature as the current target temperature, the determining a corresponding target light-emitting strip on the photodiode chip based on the current target temperature, until all target laser light having different target wavelengths are emitted.

The temperature of the photodiode chip is regulated by the semiconductor temperature controller so that the photodiode chip can emit laser light having different wavelengths at different temperatures, without the need to use multiple different independent single-wavelength laser transmitters to cooperate to complete emission of laser light having multiple different wavelengths. This reduces the use of laser apparatus chips and TO devices, reduces the complexity of installation and assembly, and also reduces the costs and the process cycle time.

It should be noted that, herein, relative terms such as “first” and “second” are only used to distinguish one entity or operation from another entity or operation, and do not necessarily require or imply that such an actual relationship or order exists between these entities or operations. Moreover, the terms “comprise”, “include”, or their any other variants are intended to cover a non-exclusive inclusion, so that a process, a method, an article, or a device that includes a list of elements not only includes those elements but also includes other elements which are not expressly listed, or further includes elements inherent to such process, method, article, or device. If no more limitations are made, an element limited by “including a/an . . . ” does not exclude other identical elements existing in the process, the method, the article, or the device which includes the element.

The above descriptions are merely specific implementations of the present disclosure, so that those skilled in the art can understand or implement the present disclosure. Various modifications to these embodiments will be readily apparent to those skilled in the art, and the general principles defined herein may be implemented in other embodiments without departing from the spirit or scope of the present disclosure. Therefore, the present disclosure will not be limited to the embodiments shown herein, but extends to the widest scope that complies with the principles and novelty disclosed in this specification.

In one aspect, a photodiode chip is provided in the present disclosure. The photodiode includes a substrate. The chip includes a grating layer above the substrate and a ridge waveguide layer located above the grating layer. The ridge waveguide layer includes multiple ridge waveguides. The grating layer includes multiple columns of gratings. Each of the multiple ridge waveguides corresponds to one column of gratings in the multiple columns of gratings below, and at least two columns of gratings in the multiple columns of gratings have different grating period pitches.

In some embodiments, any two columns of gratings in the multiple columns of gratings have different grating period pitches.

In some embodiments, grating period pitches of the multiple columns of gratings are sequentially set based on a preset change curve of a lasing wavelength and a temperature.

In some embodiments, the chip further includes electrodes covering the ridge waveguide layer, a first insulating dielectric film covering the electrodes, and electrode connection lines disposed on the first insulating dielectric film. The first insulating dielectric film defines a first opening at a position above each of the multiple ridge waveguides. Each of the electrode connection lines is connected to a corresponding electrode through a corresponding first opening.

In some embodiments, a first opening above each of the multiple ridge waveguides and a first opening above a ridge waveguide adjacent to said each of the multiple ridge waveguides are staggered from each other.

In some embodiments, the chip further includes a second insulating dielectric film disposed between each of the multiple ridge waveguides and each of the electrodes. The second insulating dielectric film wraps and covers the multiple ridge waveguides, and defines a second opening at a position above each of the multiple ridge waveguides. Each of the electrodes is in contact with a corresponding ridge waveguide through a corresponding second opening.

In some embodiments, the chip further includes multiple pads. The multiple pads are in a one-to-one correspondence with first openings above the ridge waveguide layer. Each of the electrode connection lines connects an electrode at a first opening to a corresponding pad through the first opening.

In some embodiments, the chip further includes a buffer layer, a lower waveguide layer, a quantum well layer, and an upper waveguide layer that are sequentially distributed from bottom to top above the substrate and below the grating layer. The chip further includes a corrosion stop layer between the grating layer and the ridge waveguide layer.

In some embodiments, the chip further includes a light-emitting end and a backlight end. An antireflective film is evaporated at the light-emitting end, and a reflective film is evaporated at the backlight end.

In another aspect, a photodiode is provided in the present disclosure. The photodiode includes a photodiode chip according to any one of the above embodiments.

In yet another aspect, a method for manufacturing a photodiode chip is provided in the present disclosure. The method includes the following. A grating base-layer is grown above a substrate. Grating etching is performed on the grating base-layer to obtain multiple columns of gratings. The multiple columns of gratings form a grating layer. At least two columns of gratings in the multiple columns of gratings have different grating period pitches. A ridge waveguide base-layer is grown above the grating layer. The ridge waveguide base-layer is etched to obtain multiple ridge waveguides. The multiple ridge waveguides form a ridge waveguide layer. Each of the multiple ridge waveguides corresponds to one column of gratings in the multiple columns of gratings and is located above the corresponding grating.

In some embodiments, before growing the grating base-layer above the substrate, the method further includes the following. A buffer layer, a lower waveguide layer, a quantum well layer, and an upper waveguide layer that are sequentially distributed from bottom to top are deposited and grown above the substrate by a first growth method. The grating base-layer is grown above the substrate as follows. The grating base-layer is grown above the upper waveguide layer. The ridge waveguide base-layer is grown above the grating layer as follows. A corrosion stop layer and a positively doped top-layer that are sequentially distributed from bottom to top above the grating layer are deposited and grown by the first growth method. The positively doped top-layer is the ridge waveguide base-layer. The ridge waveguide base-layer is etched to obtain the multiple ridge waveguides as follows. A corrosion passivation film is grown on the positively doped top-layer by a second growth method. The corrosion passivation film is etched by an etching processing to obtain the ridge waveguide layer and an etching-stop dielectric film that are sequentially distributed from bottom to top. The ridge waveguide layer includes the multiple ridge waveguides. After etching the ridge waveguide base-layer to obtain the multiple ridge waveguides, the method further includes the following. The etching-stop dielectric film is corroded to define a second opening above each of the multiple ridge waveguides. An electrode is manufactured above each of the multiple ridge waveguides to generate a semiconductor bar. Insulating dielectric films are deposited and grown by the second growth method on the semiconductor bar, to make the insulating dielectric films be grown between adjacent ridge waveguides in the multiple ridge waveguides, between electrodes corresponding to the adjacent ridge waveguides, and on the electrodes. A first opening is defined in an insulating dielectric film of an electrode corresponding to each of the multiple ridge waveguides. Photoetching is performed at preset pad positions to obtain pads. Photoetching is performed between each of the pads and a corresponding first opening to obtain an electrode connection line.

In some embodiments, manufacturing the electrode above each of the multiple ridge waveguides to generate the semiconductor bar includes the following. A first electrode, a second electrode, and a third electrode distributed sequentially from bottom to top are manufactured above each of the multiple ridge waveguides by using a photoresist lift-off process, to generate the semiconductor bar.

In some implementation, the method further includes the following. The back of the substrate is thinned to make the semiconductor bar to reach a preset thickness. The bar is polished. A negative electrode contact layer is evaporated on the back of the substrate. Rapid alloying is performed for preset duration at a preset temperature in a preset operating environment to form an ohmic contact. Cleavage is performed on the semiconductor bar to obtain multiple photodiode chips. An antireflective film having a reflectivity of a first reflectivity is evaporated at a light emitting end of each photodiode chip. A reflective film having a reflectivity of a second reflectivity is evaporated at the other end of the photodiode chip.

In some embodiments, the first electrode is a titanium electrode, the second electrode is a platinum electrode, and the third electrode is a gold electrode.

In yet another aspect, a method for controlling a wavelength of a photodiode is provided in the present disclosure. The method is applied to a driver electronic chip. The method includes the following. A semiconductor temperature controller is controlled to perform temperature regulation on a photodiode chip. The photodiode chip is controlled to emit target laser light having a wavelength including a corresponding target wavelength each time a temperature of the photodiode chip reaches a target temperature. The target wavelength is related to the target temperature. The target laser light has a spectrum width.

In some embodiments, the temperature regulation is progressive temperature regulation corresponding to multiple different temperature regulation moments.

In some embodiments, the semiconductor temperature controller is controlled to perform the temperature regulation on the photodiode chip as follows. Different operating voltages are set for the semiconductor temperature controller at different temperature regulation moments, to make the semiconductor temperature controller perform the temperature regulation on the photodiode chip under the different operating voltages.

In some embodiments, the photodiode chip is controlled to emit the target laser light having the wavelength including the corresponding target wavelength each time the temperature of the photodiode chip reaches the target temperature as follows. A ridge waveguide of the photodiode chip that corresponds to each target temperature is determined. Energization control is performed on a corresponding ridge waveguide at each moment, to make each ridge waveguide energize a quantum well layer of the photodiode chip and make the photodiode chip emit the target laser light having the wavelength including the corresponding target wavelength.

In some embodiments, the ridge waveguide of the photodiode chip that corresponds to each target temperature is determined as follows. The corresponding target wavelength is determined based on the target temperature. The corresponding ridge waveguide of the photodiode chip is determined based on the target wavelength.

In some embodiments, each ridge waveguide of the photodiode chip defines an opening. The photodiode chip further includes pads, electrode connection lines, and electrodes that each are in a one-to-one correspondence with each opening. Each of the pads is connected to a corresponding ridge waveguide by using a corresponding electrode connection line passing through a corresponding opening.

In some embodiments, the energization control is performed on the corresponding ridge waveguide at each moment as follows. At each moment, energization driving is performed on the pad connected to the corresponding ridge waveguide, to perform the energization control on the corresponding ridge waveguide by the pad.

In some embodiments, the method further includes the following. A corresponding grating of the photodiode chip is determined based on a ridge waveguide corresponding to the target wavelength. The corresponding grating is enabled to perform grating screening on target laser light corresponding to the target temperature to obtain corresponding laser light having a narrow spectrum width. The laser light having the narrow spectrum width is used as the target laser light corresponding to the target temperature.

In some embodiments, the corresponding grating is enabled to perform grating screening on the target laser light corresponding to the target temperature to obtain the corresponding laser light having the narrow spectrum width as follows. The corresponding grating is enabled to perform total reflection on the target laser light corresponding to the target temperature through a rear edge of the grating, and to perform semi-transmission and semi-reflection on the target laser light through a front edge of the grating, to make carriers of the target laser light oscillate in the grating to obtain the corresponding laser light having the narrow spectrum width.

In yet another aspect, a photodiode is provided in the present disclosure. The photodiode includes a photodiode chip, a semiconductor temperature controller, and a driver electronic chip. The semiconductor temperature controller is located on one side of the photodiode chip. The photodiode is configured to emit laser light having different wavelengths by the above method.

In some embodiments, a grating cavity of the photodiode chip has a length greater than 2 mm.

In some embodiments, the grating is grown under the corresponding ridge waveguide by using electron beam lithography or holography.

In yet another aspect, a photodiode is provided in the present disclosure. The photodiode includes a photodiode chip, a semiconductor temperature controller, and a driver electronic chip. The photodiode chip includes a substrate. The chip includes a grating layer above the substrate and a ridge waveguide layer located above the grating layer. The ridge waveguide layer includes multiple ridge waveguides. The grating layer includes multiple columns of gratings. Each of the multiple ridge waveguides corresponds to one column of gratings in the multiple columns of gratings below, and at least two columns of gratings in the multiple columns of gratings have different grating period pitches. The semiconductor temperature controller is located on one side of the photodiode chip and configured to regulate a temperature of the photodiode chip to a target temperature. The driver electronic chip is configured to perform energization control on the photodiode chip that is at the target temperature, to make the photodiode chip at the target temperature emit target laser light having a wavelength including a corresponding target wavelength. The target wavelength is related to the target temperature. The target laser light has a spectrum width.

In some embodiments, the photodiode chip includes a quantum well layer and multiple ridge waveguides. The driver electronic chip is configured to perform energization control on a ridge waveguide corresponding to the target temperature, to make the quantum well layer be energized by the ridge waveguide to form ion inversion, to emit the target laser light having the wavelength including the corresponding target wavelength.

In some embodiments, the photodiode chip further includes multiple pads, multiple electrode connection lines, and multiple electrodes that are in a one-to-one correspondence with each other. Each of the multiple pads is connected to a corresponding ridge waveguide by sequentially using a corresponding electrode connection line and a corresponding electrode. The driver electronic chip is further configured to perform energization control on the corresponding ridge waveguide by sequentially using a corresponding pad, a corresponding electrode connection line, and a corresponding electrode that are in a one-to-one correspondence with each other.

In some embodiments, the photodiode chip further includes the multiple columns of gratings. Each of the multiple ridge waveguides corresponds to one column of gratings in the multiple columns of gratings. A corresponding grating is configured to perform grating screening on target laser light corresponding to the corresponding ridge waveguide, to make a spectrum width of the corresponding target laser light reach a target spectrum width.

In some embodiments, a first opening and a second opening are defined above each of the multiple ridge waveguides. Each of the multiple pads is connected to the corresponding electrode by using the corresponding electrode connection line passing through a corresponding first opening. There is no contact between any two electrode connection lines, between any two ridge waveguides, between any two electrodes, and between any two pads.

In some embodiments, a grating cavity of the photodiode chip has a length greater than 2 mm.

In some embodiments, the driver electronic chip is connected to the semiconductor temperature controller. The driver electronic chip is configured to set different voltages for the semiconductor temperature controller, to make the semiconductor temperature controller regulate different temperatures for the photodiode chip.

In some embodiments, the photodiode further includes a ceramic carrier, and the photodiode chip, the semiconductor temperature controller, and the driver electronic chip are all arranged on the ceramic carrier.

In some embodiments, a rear edge of the grating is configured to perform total reflection, and a front edge of the grating is configured to perform semi-transmission and semi-reflection.

In some embodiments, grating period pitches of the multiple columns of gratings are sequentially set based on a preset change curve of a lasing wavelength and a temperature.

In some embodiments, the grating is made of an indium gallium arsenide phosphide (InGaAsP) grating material. A grating period pitch of each grating is a ratio of a corresponding target wavelength to twice a refractive index of the grating material.

In yet another aspect, a photodiode chip is provided in the present disclosure. The photodiode chip is an integral part of the foregoing photodiode. The chip includes a substrate. The chip includes a grating layer above the substrate and a ridge waveguide layer located above the grating layer. The ridge waveguide layer includes multiple ridge waveguides. The grating layer includes multiple columns of gratings. Each of the ridge waveguides corresponds to one column of gratings in the multiple columns of gratings below. At least two columns of gratings in the multiple columns of gratings have different grating period spacings.

In some embodiments, an electrode is etched above each ridge waveguide. An insulating dielectric film is grown between adjacent ridge waveguides in the multiple ridge waveguides, between electrodes corresponding to the adjacent ridge waveguides, and on the electrodes. An opening is defined in an insulating dielectric film of each electrode. The chip further includes multiple pads. Each of the pads is connected to a corresponding electrode by using a corresponding electrode connection line passing through a corresponding opening.

In some embodiments, the chip further includes a buffer layer, a lower waveguide layer, a quantum well layer, and an upper waveguide layer that are sequentially distributed from bottom to top above the substrate and below the grating layer. The chip further includes a corrosion stop layer between the grating layer and the ridge waveguide layer.

In yet another aspect, a method for controlling a wavelength of a photodiode is provided in the present disclosure. The method is applied to a laser apparatus. The laser apparatus includes a photodiode, a semiconductor temperature controller, and a driver electronic chip. The photodiode includes a photodiode chip. The photodiode includes a substrate. The chip includes a grating layer above the substrate and a ridge waveguide layer located above the grating layer. The ridge waveguide layer includes multiple ridge waveguides. The grating layer includes multiple columns of gratings. Each of the multiple ridge waveguides corresponds to one column of gratings in the multiple columns of gratings below, and at least two columns of gratings in the multiple columns of gratings have different grating period pitches. The semiconductor temperature controller is located on one side of the photodiode chip and configured to regulate a temperature of the photodiode chip to a target temperature. The driver electronic chip is configured to perform energization control on the photodiode chip that is at the target temperature, to make the photodiode chip at the target temperature emit target laser light having a wavelength including a corresponding target wavelength. The target wavelength is related to the target temperature. The target laser light has a spectrum width. The photodiode chip is a photodiode chip. The photodiode chip is provided with multiple light-emitting strips and multiple pairs of electrodes. Each light-emitting strip corresponds to one pair of electrodes. The method includes the following. A user instruction is received. The semiconductor temperature controller is controlled, according to the user instruction, to control a temperature of the photodiode chip, to make the temperature of the photodiode chip reach a current target temperature at a current moment. A corresponding target light-emitting strip on the photodiode chip is determined based on the current target temperature. The driver electronic chip is controlled to energize one pair of electrodes corresponding to the target light-emitting strip, to make the pair of electrodes corresponding to the target light-emitting strip act on the target light-emitting strip, to enable the target light emitting strip to emit target laser light having a wavelength including a target wavelength. The target laser light has a spectrum width. The semiconductor temperature controller is controlled, according to the user instruction, to control the temperature of the photodiode chip, to make the temperature of the photodiode chip reach a next-moment target temperature at a next moment of the current moment. By using the next-moment target temperature as the current target temperature, determining the corresponding target light-emitting strip on the photodiode chip based on the current target temperature is performed, until all target laser light having different target wavelengths are emitted. The target laser light has a spectrum width.

In some embodiments, after the target light-emitting strip is enabled to emit the target laser light having the wavelength including the target wavelength, the method further includes the following. The photodiode chip is controlled to perform wavelength screening on the target laser light, to make a spectrum width of the target laser light reach a preset spectrum width.

In some embodiments, the corresponding target light-emitting strip on the photodiode chip is determined based on the current target temperature as follows. A light-emitting strip corresponding to the current target temperature is searched for in a preset comparison list. The found light-emitting strip is used as the target light-emitting strip.

In some embodiments, the driver electronic chip is controlled to energize the pair of electrodes corresponding to the target light-emitting strip, to make the pair of electrodes corresponding to the target light-emitting strip act on the target light-emitting strip, to enable the target light-emitting strip to emit the target laser light having the wavelength including the target wavelength as follows. The driver electronic chip is controlled to energize the pair of electrodes corresponding to the target light-emitting strip, to make the pair of electrodes corresponding to the target light-emitting strip perform energization modulation on a quantum well layer of the target light-emitting strip by using a ridge waveguide on the target light-emitting strip, to enable the target laser light having the wavelength including the target wavelength to be emitted from the target light-emitting strip.

In some embodiments, the photodiode chip is controlled to perform the wavelength screening on the target laser light, to make the spectrum width of the target laser light reach the preset spectrum width as follows. A grating corresponding to the ridge waveguide on the target light-emitting strip is controlled to perform the grating screening on the target laser light, to make the spectrum width of the target laser light after the grating screening reach the preset spectrum width.

In some embodiments, the grating corresponding to the ridge waveguide on the target light-emitting strip is controlled to perform the grating screening on the target laser light as follows. The grating corresponding to the ridge waveguide on the target light-emitting strip is controlled to perform total reflection on the target laser light through a rear edge of the grating, and to perform semi-transmission and semi-reflection on the target laser light through a front edge of the grating, to make carriers of the target laser light oscillate in the grating to obtain laser light having a specific wavelength.

In some embodiments, the grating is formed under the corresponding ridge waveguide by using electron beam lithography.

In some embodiments, a grating cavity of the photodiode chip has a length greater than 2 mm.

In some embodiments, 12 or 14 light emitting strips are disposed on the photodiode chip.

In yet another aspect, an apparatus for controlling a wavelength of a photodiode is provided in the present disclosure. The photodiode chip is provided with multiple light-emitting strips and multiple pairs of electrodes. Each of the multiple light-emitting strips corresponds to one pair of electrodes in the multiple pairs of electrodes. The apparatus includes a temperature control module, a matching module, an energization module, and a loop module. The temperature control module is configured to receive a user instruction, and control, according to the user instruction, a semiconductor temperature controller to control a temperature of the photodiode chip, to make the temperature of the photodiode chip reach a current target temperature at a current moment. The matching module is configured to determine a corresponding target light-emitting strip on the photodiode chip based on the current target temperature. The energization module is configured to control the driver electronic chip to energize one pair of electrodes corresponding to the target light-emitting strip, to make the pair of electrodes corresponding to the target light-emitting strip act on the target light-emitting strip, to enable the target light-emitting strip to emit target laser light having a wavelength including a target wavelength. The target laser light has a spectrum width. The loop module is configured to control, according to the user instruction, the semiconductor temperature controller to control the temperature of the photodiode chip, to make the temperature of the photodiode chip reaches a next-moment target temperature at a next moment of the current moment, and perform, by using the next-moment target temperature as the current target temperature, determining the corresponding target light-emitting strip on the photodiode chip based on the current target temperature, until all target laser light having different target wavelengths are emitted.

In yet another aspect, a computer-readable storage medium is provided in the present disclosure. A computer program is stored on the computer-readable storage medium. When the computer program is executed by a processor, the processor performs the operations of the method according to any one of the foregoing embodiments.

In yet another aspect, a computer device is provided in the present disclosure. The computer device includes a memory, a processor, and a computer program stored on the memory and operable on the processor. When the processor executes the program, the operations of the method according to any one of the foregoing embodiments are performed.

The photodiode chip provided in some technical solutions of the present disclosure sequentially includes the grating layer above the substrate and the ridge waveguide layer located above the grating layer, the ridge waveguide layer includes the multiple ridge waveguides, the grating layer includes the multiple columns of gratings, each of the ridge waveguides corresponds to one column of gratings in the multiple columns of gratings below, and at least two columns of gratings of the multiple columns of gratings have different grating period pitches. Different ridge waveguides of the photodiode chip can emit light having different center wavelengths, and wavelength screening of the emitted light is performed by using a corresponding grating to obtain target laser light having a specific spectrum width. With the photodiode chip, it is not required to use multiple photodiode chips and TO devices to emit laser light having different wavelengths as in the prior art. Therefore, some technical solutions of the present disclosure can reduce the complexity of installation and assembly and also reduce the costs and the process cycle time due to less instrumentation.

In some technical solutions of the present disclosure, the driver electronic chip controls the semiconductor temperature controller to regulate the temperature of the photodiode chip; and the driver electronic chip controls the photodiode chip to emit target laser light having a wavelength including a corresponding target wavelength each time the temperature of the photodiode chip reaches a target temperature, where the target wavelength is related to the target temperature, and the target laser light has a spectrum width. Through some embodiments of the present disclosure, the temperature of the photodiode chip can be regulated such that the photodiode chip can emit laser light having different wavelengths at different temperatures, thereby reducing the use of photodiode chips and TO devices, reducing the complexity of installation and assembly, and also reducing the costs and the process cycle time.

Some technical solutions of the present disclosure involve receiving the user instruction, and controlling, according to the user instruction, the semiconductor temperature controller to control the temperature of the photodiode chip, such that the temperature of the photodiode chip reaches the current target temperature at the current moment; determining the corresponding target light-emitting strip on the photodiode chip based on the current target temperature; controlling the driver electronic chip to energize one pair of electrodes corresponding to the target light-emitting strip, such that the pair of electrodes corresponding to the target light-emitting strip acts on the target light-emitting strip, so as to enable the target light-emitting strip to emit target laser light having a wavelength including a target wavelength, the target laser light having a spectrum width; and controlling, according to the user instruction, the semiconductor temperature controller to control the temperature of the photodiode chip, such that the temperature of the photodiode chip reaches the next-moment target temperature at the next moment of the current moment, and performing, by using the next-moment target temperature as the current target temperature, the determining a corresponding target light-emitting strip on the photodiode chip based on the current target temperature, until all target laser light having different target wavelengths are emitted. The temperature of the photodiode chip can be regulated such that the photodiode chip can emit laser light having different wavelengths, thereby reducing the use of laser apparatus chips and TO devices, reducing the complexity of installation and assembly, and also reducing the costs and the process cycle time.

1. A photodiode chip, comprising a substrate, wherein the chip comprises a grating layer above the substrate and a ridge waveguide layer located above the grating layer, the ridge waveguide layer comprises a plurality of ridge waveguides, the grating layer comprises a plurality of columns of gratings, each of the plurality of ridge waveguides corresponds to one column of gratings in the plurality of columns of gratings below, and at least two columns of gratings in the plurality of columns of gratings have different grating period pitches.

2. The chip according to claim 1, wherein any two columns of gratings in the plurality of columns of gratings have different grating period pitches.

3. The chip according to claim 1, wherein grating period pitches of the plurality of columns of gratings are sequentially set based on a preset change curve of a lasing wavelength and a temperature.

4. The chip according to claim 1, further comprising electrodes covering the ridge waveguide layer, a first insulating dielectric film covering the electrodes, and electrode connection lines disposed on the first insulating dielectric film, wherein the first insulating dielectric film defines a first opening at a position above each of the plurality of ridge waveguides, and each of the electrode connection lines is connected to a corresponding electrode through a corresponding first opening.

5. The chip according to claim 4, wherein a first opening above each of the plurality of ridge waveguides and a first opening above a ridge waveguide adjacent to said each of the plurality of ridge waveguides are staggered from each other.

6. The chip according to claim 4, further comprising a second insulating dielectric film disposed between each of the plurality of ridge waveguides and each of the electrodes, wherein the second insulating dielectric film wraps and covers the plurality of ridge waveguides and defines a second opening at a position above each of the plurality of ridge waveguides, and each of the electrodes is in contact with a corresponding ridge waveguide through a corresponding second opening.

7. The chip according to claim 4, further comprising a plurality of pads, wherein the plurality of pads are in a one-to-one correspondence with first openings above the ridge waveguide layer, and each of the electrode connection lines connects an electrode at a first opening to a corresponding pad through the first opening.

8. The chip according to claim 7, further comprising: a buffer layer, a lower waveguide layer, a quantum well layer, and an upper waveguide layer that are sequentially distributed from bottom to top above the substrate and below the grating layer, wherein the chip further comprises a corrosion stop layer between the grating layer and the ridge waveguide layer.

9. The chip according to claim 1, further comprising a light-emitting end and a backlight end, wherein an antireflective film is evaporated at the light-emitting end, and a reflective film is evaporated at the backlight end.

10-22. (canceled)

23. A photodiode, comprising a photodiode chip, a semiconductor temperature controller, and a driver electronic chip, wherein the photodiode chip comprises a substrate, wherein the chip comprises a grating layer above the substrate and a ridge waveguide layer located above the grating layer, the ridge waveguide layer comprises a plurality of ridge waveguides, the grating layer comprises a plurality of columns of gratings, each of the plurality of ridge waveguides corresponds to one column of gratings in the plurality of columns of gratings below, and at least two columns of gratings in the plurality of columns of gratings have different grating period pitches; wherein the semiconductor temperature controller is located on one side of the photodiode chip and configured to regulate a temperature of the photodiode chip to a target temperature, and the driver electronic chip is configured to perform energization control on the photodiode chip that is at the target temperature, to make the photodiode chip at the target temperature emit target laser light having a wavelength comprising a corresponding target wavelength, wherein the target wavelength is related to the target temperature, and the target laser light has a spectrum width.

24. The photodiode according to claim 23, wherein the photodiode chip comprises a quantum well layer and a plurality of ridge waveguides, and the driver electronic chip is configured to perform energization control on a ridge waveguide corresponding to the target temperature, to make the quantum well layer be energized by the ridge waveguide to form ion inversion, to emit the target laser light having the wavelength comprising the corresponding target wavelength.

25. The photodiode according to claim 24, wherein the photodiode chip further comprises a plurality of pads, a plurality of electrode connection lines, and a plurality of electrodes that are in a one-to-one correspondence with each other, each of the plurality of pads is connected to a corresponding ridge waveguide by sequentially using a corresponding electrode connection line and a corresponding electrode, and the driver electronic chip is further configured to perform energization control on the corresponding ridge waveguide by sequentially using a corresponding pad, a corresponding electrode connection line, and a corresponding electrode that are in a one-to-one correspondence with each other.

26. The photodiode according to claim 25, wherein the photodiode chip further comprises the plurality of columns of gratings, each of the plurality of ridge waveguides corresponds to one column of gratings in the plurality of columns of gratings, and a corresponding grating is configured to perform grating screening on target laser light corresponding to the corresponding ridge waveguide, to make a spectrum width of the corresponding target laser light reach a target spectrum width.

27. The photodiode according to claim 26, wherein a first opening and a second opening are defined above each of the plurality of ridge waveguides, and each of the plurality of pads is connected to the corresponding electrode by using the corresponding electrode connection line passing through a corresponding first opening, wherein
there is no contact between any two electrode connection lines, between any two ridge waveguides, between any two electrodes, and between any two pads.

28-32. (canceled)

33. A method for controlling a wavelength of a photodiode, applied to a laser apparatus, the laser apparatus comprising a photodiode, a semiconductor temperature controller, and a driver electronic chip, wherein the photodiode comprises a photodiode chip; wherein the photodiode chip comprises a substrate, wherein the chip comprises a grating layer above the substrate and a ridge waveguide layer located above the grating layer, the ridge waveguide layer comprises a plurality of ridge waveguides, the grating layer comprises a plurality of columns of gratings, each of the plurality of ridge waveguides corresponds to one column of gratings in the plurality of columns of gratings below, and at least two columns of gratings in the plurality of columns of gratings have different grating period pitches; wherein the semiconductor temperature controller is located on one side of the photodiode chip and configured to regulate a temperature of the photodiode chip to a target temperature, and the driver electronic chip is configured to perform energization control on the photodiode chip that is at the target temperature, to make the photodiode chip at the target temperature emit target laser light having a wavelength comprising a corresponding target wavelength, wherein the target wavelength is related to the target temperature, and the target laser light has a spectrum width; wherein the photodiode chip is provided with a plurality of light-emitting strips and a plurality of pairs of electrodes, each light-emitting strip corresponds to one pair of electrodes, and the method comprises:
receiving a user instruction, and controlling, according to the user instruction, the semiconductor temperature controller to control a temperature of the photodiode chip, to make the temperature of the photodiode chip reach a current target temperature at a current moment;
determining a corresponding target light-emitting strip on the photodiode chip based on the current target temperature;
controlling the driver electronic chip to energize one pair of electrodes corresponding to the target light-emitting strip, to make the pair of electrodes corresponding to the target light-emitting strip act on the target light-emitting strip, to enable the target light emitting strip to emit target laser light having a wavelength comprising a target wavelength, the target laser light having a spectrum width; and
controlling, according to the user instruction, the semiconductor temperature controller to control the temperature of the photodiode chip, to make the temperature of the photodiode chip reach a next-moment target temperature at a next moment of the current moment, and performing, by using the next-moment target temperature as the current target temperature, determining the corresponding target light-emitting strip on the photodiode chip based on the current target temperature, until all target laser light having different target wavelengths are emitted.

34. The method according to claim 33, wherein after the target light-emitting strip is enabled to emit the target laser light having the wavelength comprising the target wavelength, the method further comprises:
controlling the photodiode chip to perform wavelength screening on the target laser light, to make a spectrum width of the target laser light reach a preset spectrum width.

35. The method according to claim 34, wherein determining the corresponding target light-emitting strip on the photodiode chip based on the current target temperature comprises:
searching for a light-emitting strip corresponding to the current target temperature in a preset comparison list, and using the found light-emitting strip as the target light-emitting strip.

36. The method according to claim 35, wherein controlling the driver electronic chip to energize the pair of electrodes corresponding to the target light-emitting strip, to make the pair of electrodes corresponding to the target light-emitting strip act on the target light-emitting strip, to enable the target light-emitting strip to emit the target laser light having the wavelength comprising the target wavelength comprises:
controlling the driver electronic chip to energize the pair of electrodes corresponding to the target light-emitting strip, to make the pair of electrodes corresponding to the target light-emitting strip perform energization modulation on a quantum well layer of the target light-emitting strip by using a ridge waveguide on the target light-emitting strip, to enable the target laser light having the wavelength comprising the target wavelength to be emitted from the target light-emitting strip.

37. The method according to claim 36, wherein controlling the photodiode chip to perform the wavelength screening on the target laser light, to make the spectrum width of the target laser light reach the preset spectrum width comprises:
controlling a grating corresponding to the ridge waveguide on the target light-emitting strip to perform the grating screening on the target laser light, to make the spectrum width of the target laser light after the grating screening reach the preset spectrum width.

38. The method according to claim 37, wherein the controlling the grating corresponding to the ridge waveguide on the target light-emitting strip to perform the grating screening on the target laser light comprises:
controlling the grating corresponding to the ridge waveguide on the target light-emitting strip to perform total reflection on the target laser light through a rear edge of the grating, and to perform semi-transmission and semi-reflection on the target laser light through a front edge of the grating, to make carriers of the target laser light oscillate in the grating to obtain laser light having a specific wavelength.

39-42. (canceled)
